(19) United States
(12) Patent Application Publication
(10) Pub. No.: US 2015/0179955 A1
(43) Pub. Date: Jun. 25, 2015

(54) COMPOUND FOR ORGANIC ELECTROLUMINESCENCE DEVICE AND ORGANIC ELECTROLUMINESCENCE DEVICE INCLUDING THE SAME

(71) Applicant: SAMSUNG DISPLAY CO., LTD., Yongin-City (KR)

(72) Inventor: Yasuo MIYATA, Yokohama (JP)

(21) Appl. No.: 14/574,192

(22) Filed: Dec. 17, 2014

(30) Foreign Application Priority Data
Dec. 20, 2013 (JP) 2013-264635
Dec. 20, 2013 (JP) 2013-264641

(51) Int. Cl. H01L 51/00

(52) U.S. Cl. CPC H01L 51/0072; H01L 51/0073; H01L 51/0074; H01L 51/5012

(57) ABSTRACT

A compound for an organic electroluminescence (EL) device, the compound being represented by the following Formula (1):

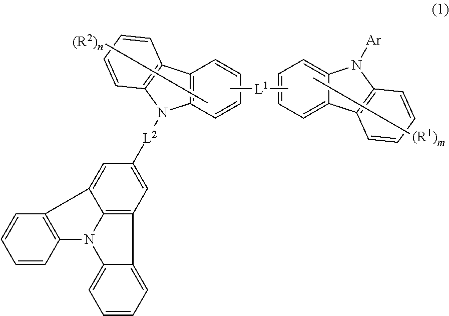

### CROSS-REFERENCE TO RELATED APPLICATION

Japanese Patent Application Nos. 2013-264635 and 2013-264641, filed on Dec. 20, 2013, in the Japanese Patent Office, and entitled: “Material for Organic Electroluminescence Device and Organic Electroluminescence Device Having the Same,” are incorporated by reference herein in their entirety.

### BACKGROUND

1. Field

Embodiments relate to a compound for an organic electroluminescence device and an organic electroluminescence device including the same.

2. Description of the Related Art

In recent years, organic electroluminescence (EL) displays (that are one type of image displays) have been actively developed. Unlike a liquid crystal display and the like, the organic EL display is a self-luminescent display in which holes and electrons injected from an anode and a cathode may be recombined in an emission layer to thus emit light from a light-emitting material (including an organic compound of the emission layer), thereby performing display.

An example of an organic electroluminescence device (hereinafter referred to as an organic EL device) is an organic EL device that includes an anode, a hole transport layer on the anode, an emission layer on the hole transport layer, an electron transport layer on the emission layer, and a cathode on the electron transport layer. Holes injected from the anode may be injected into the emission layer via the hole transport layer. Meanwhile, electrons may be injected from the cathode, and then injected into the emission layer via the electron transport layer. The holes and the electrons injected into the emission layer may be recombined to generate excitons within the emission layer. The organic EL device may emit light by using lights generated during the transition of the excitons to a ground state.

### SUMMARY

Embodiments are directed to a compound for an organic electroluminescence device and an organic electroluminescence device including the same.

The embodiments may be realized by providing a compound for an organic electroluminescence (EL) device, the compound being represented by the following Formula (1):

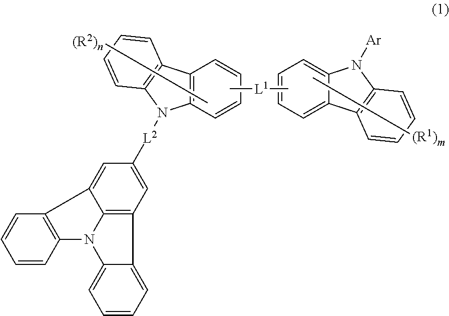

wherein, in Formula (1), Ar is a substituted or unsubstituted alkyl group, a substituted or unsubstituted aryl group, or a substituted or unsubstituted heteroaryl group, L¹ and L² are each independently a single bond, a substituted or unsubstituted arylene group, or a substituted or unsubstituted heteroarylene group, R¹ and R² are each independently hydrogen, deuterium, a halogen atom, a cyano group, a substituted or unsubstituted alkyl group, a substituted or unsubstituted alkoxy group, a substituted or unsubstituted aryl group, a substituted or unsubstituted heteroaryl group, a substituted or unsubstituted triarylsilyl group, or a substituted or unsubstituted trialkylsilyl group, and m and n are each independently an integer of 1 to 7.

Ar may be a substituted or unsubstituted aryl group having 6 to 24 ring carbon atoms.

Ar may be a substituted or unsubstituted carbazolyl group, a substituted or unsubstituted dibenzofuryl group, or a substituted or unsubstituted dibenzothienyl group.

L¹ and L² may each independently be a single bond or a substituted or unsubstituted arylene group having 6 to 18 ring carbon atoms.

R¹ and R² may each independently be hydrogen or a substituted or unsubstituted aryl group.

The embodiments may be realized by providing a hole transport material comprising the compound for an organic EL device according to an embodiment.

The embodiments may be realized by providing an organic electroluminescence (EL) device including an anode; an emission layer; and at least one layer between the anode and the emission layer, the at least one layer including the hole transport material according to an embodiment.

The embodiments may be realized by providing a host material including the compound for an organic EL device according to an embodiment.

The embodiments may be realized by providing an organic electroluminescence (EL) device including an anode; an emission layer; and at least one layer between the anode and the emission layer, the at least one layer including the hole transport material according to an embodiment.

### BRIEF DESCRIPTION OF THE DRAWINGS

Features will be apparent to those of skill in the art by describing in detail exemplary embodiments with reference to the attached drawings in which:

FIG. 1 illustrates a schematic diagram of an organic EL device according to an embodiment; and

FIG. 2 illustrates a schematic diagram of an organic EL device according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

An organic EL device having improved electron tolerance, high efficiency, and long life may be manufactured by using a carbazole coupled compound (with high hole transporting properties) substituted with an indolocarbazolyl group (with high electron tolerance).

The material or compound for an organic EL device according to an embodiment may include a carbazole coupled compound substituted with an indolocarbazolyl group. In an implementation, the compound may be represented by the following Formula (1).

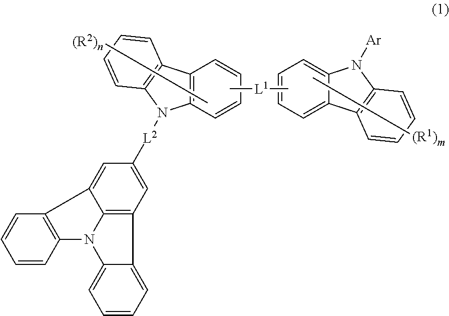

In Formula (1), Ar may be, e.g., a substituted or unsubstituted alkyl group, a substituted or unsubstituted aryl group, or a substituted or unsubstituted heteroaryl group.

The alkyl group of Ar may be a substituted or unsubstituted alkyl group having 1 to 30 carbon atoms. In an implementation, the alkyl group may include, e.g., a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, a n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantly group, a 2-ethyldecyl group, a 2-butyldecyl group, a 2-hexyldecyl group, a 2-octyldecyl group, an n-undecyl group, an n-dodecyl group, a 2-ethyldocecyl group, a 2-butyldodecyl group, a 2-hexyldodecyl group, a 2-octyldodecyl group, an n-tridecyl group, an n-tetradecyl group, an n-pentadecyl group, an n-hexadecyl group, a 2-ethylhexadecyl group, 2-butylhexadecyl group, a 2-hexylhexadecyl group, a 2-octylhexadecyl group, an n-heptadecyl group, an n-octadecyl group, an n-nanodecyl group, an n-icosyl group, a 2-ethylicosyl group, a 2-butylicosyl group, a 2-hexylicosyl group, a 2-octylicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, or the like.

The aryl group of Ar may be a substituted or unsubstituted aryl group having 6 to 24 ring carbon atoms. In an implementation, the aryl group may include, e.g., a phenyl group, a naphthyl group, an anthracenyl group, a phenanthryl group, a biphenyl group, a terphenyl group, a quaterphenyl group, a fluorenyl group, a triphenylene group, a biphenylene group, a pyrenyl group, a benzofluoranthenyl group, a chrysenyl group, or the like.

The heteroaryl group of Ar may be a substituted or unsubstituted heteroaryl group having 4 to 30 ring carbon atoms (e.g., 5 to 35 total ring atoms). In an implementation, the heteroaryl group may include, e.g., a benzothiazolyl group, a thiophenyl group, a thienothiophenyl group, a thienothienothiophenyl group, a benzothiophenyl group, a benzofuryl group, a dibenzothiophenyl group, a dibenzofuryl group, an N-arylcarbazolyl group, an N-heteroarylcarbazolyl group, an N-alkylcarbazolyl group, a phenoxazyl group, a phenothiazyl group, a pyridyl group, a pyrimidyl group, a trazinyl group, a quinolinyl group, a quinoxalyl group, or the like.

In Formula (1), L¹ and L² may each independently be, e.g., a single bond, a substituted or unsubstituted arylene group, or a substituted or unsubstituted heteroarylene group. In the case that L² is a substituted or unsubstituted arylene group or a substituted or unsubstituted heteroarylene group, the electron tolerance of the material for an organic EL device according to an embodiment may be improved. In an implementation, L² may be, e.g., the substituted or unsubstituted arylene group or the substituted or unsubstituted heteroarylene group.

The arylene group of L¹ and L² may be a substituted or unsubstituted arylene group having 6 to 18 ring carbon atoms. In an implementation, the arylene group may include, e.g., a phenylene group, a naphthylene group, an anthracene group, a phenanthrylene group, a biphenylene group, a terphenylene group, a fluorenylene group, a triphenylene group, a biphenylene group, a pyrenylene group, a chrysenylene group, or the like.

The heteroarylene group of L¹ and L² may be a substituted or unsubstituted heteroarylene group having 4 to 20 ring carbon atoms (e.g., 5 to 25 total ring atoms). In an implementation, the heteroarylene group may include, e.g., a benzothiazolylene group, a thiophenylene group, a thienothiophenylene group, a thienothienothiophenylene group, a benzothiophenylene group, a benzofurylene group, a dibenzothiophenylene group, a dibenzofurylene group, an N-carbazolylene group, an N-heteroarylcarbazolylene group, an N-alkylcarbazolylene group, a phenoxazylene group, a phenothiazylene group, a pyridylene group, a pyrimidylene group, a trazinylene group, a quinolinylene group, a quinoxalylene group, or the like.

In Formula (1), R¹ and R² may each independently be, e.g., hydrogen, deuterium, a halogen atom, a cyano group, a substituted or unsubstituted alkyl group, a substituted or unsubstituted alkoxy group, a substituted or unsubstituted aryl group, a substituted or unsubstituted heteroaryl group, a substituted or unsubstituted triarylsilyl group, or a substituted or unsubstituted trialkylsilyl group. Each R¹ may be the same or different. In an implementation, each R² may be the same or different.

The alkyl group of R¹ and R² may be a substituted or unsubstituted alkyl group having 1 to 30 carbon atoms. In an implementation, the alkyl group may include, e.g., a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, a n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantly group, a 2-ethyldecyl group, a 2-butyldecyl group, a 2-hexyldecyl group, a 2-octyldecyl group, an n-undecyl group, an n-dodecyl group, a 2-ethyldocecyl group, a 2-butyldodecyl group, a 2-hexyldodecyl group, a 2-octyldodecyl group, an n-tridecyl group, an n-tetradecyl group, an n-pentadecyl group, an n-hexadecyl group, a 2-ethylhexadecyl group, 2-butylhexadecyl group, a 2-hexylhexadecyl group, a 2-octylhexadecyl group, an n-heptadecyl group, an n-octadecyl group, an n-nanodecyl group, an n-icosyl group, a 2-ethylicosyl group, a 2-butylicosyl group, a 2-hexylicosyl group, a 2-octylicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, or the like.

The alkoxy group of R¹ and R² may be a substituted or unsubstituted alkoxy group having 1 to 30 carbon atoms. In an implementation, the alkoxy group may include, e.g., a methoxy group, an ethoxy group, an n-propoxy group, an i-propoxy group, an n-butoxy group, an s-butoxy group, a t-butoxy group, an i-butoxy group, a 2-ethylbutoxy group, a 3,3-dimethylbutoxy group, an n-pentyloxy group, an i-pentyloxy group, a neopentyloxy group, a t-pentyloxy group, a cyclopentyloxy group, a 1-methylpentyloxy group, a 3-methylpentyloxy group, a 2-ethylpentyloxy group, a 4-methyl-2-pentyloxy group, an n-hexyloxy group, a 1-methylhexyloxy group, a 2-ethylhexyloxy group, a 2-butylhexyloxy group, a cyclohexyloxy group, a 4-methylcyclohexyloxy group, a 4-t-butylcyclohexyloxy group, an n-heptyloxy group, a 1-methylheptyloxy group, a 2,2-dimethylheptyloxy group, a 2-ethylheptyloxy group, 2-butylheptyloxy group, an n-octyloxy group, a t-octyloxy group, a 2-ethyloctyloxy group, a 2-butyloctyloxy group, a 2-hexyloctyloxy group, a 3,7-dimethyloctyloxy group, a cyclooctyloxy group, an n-nonyloxy group, an n-decyloxy group, an adamantyloxy group, a 2-ethyldecyloxy group, a 2-butyldecyloxy group, a 2-hexyldecyloxy group, a 2-octyldecyloxy group, an n-undecyloxy group, an n-dodecyloxy group, a 2-ethyldodecyloxy group, a 2-butyldodecyloxy group, a 2-hexyldodecyloxy group, a 2-octyldodecyloxy group, an n-tridecyloxy group, an n-tetradecyloxy group, an n-pentadecyloxy group, an n-hexadecyloxy group, a 2-ethylhexadecyloxy group, a 2-butylhexadecyloxy group, a 2-hexylhexadecyloxy group, a 2-octylhexadecyloxy group, an n-heptadecyloxy group, an n-octadecyloxy group, an n-nonadecyloxy group, an n-icosyloxy group, a 2-ethylicosyloxy group, a 2-butylicosyloxy group, a 2-hexylicosyloxy group, a 2-octylicosyloxy group, an n-henicosyloxy group, an n-docosyloxy group, an n-tricosyloxy group, an n-tetracosyloxy group, an n-pentacosyloxy group, an n-hexacosyloxy group, an n-heptacosyloxy group, an n-octacosyloxy group, an n-nonacosyloxy group, an n-triacontyloxy group, or the like.

The aryl group of R¹ and R² may be a substituted or unsubstituted aryl group having 6 to 24 ring carbon atoms. In an implementation, the aryl group may include, e.g., a phenyl group, a naphthyl group, an anthracenyl group, a phenanthryl group, a biphenyl group, a terphenyl group, a quaterphenyl group, a fluorenyl group, a triphenylene group, a biphenylene group, a pyrenyl group, a benzofluoranthenyl group, a chrysenyl group, or the like.

The heteroaryl group of R¹ and R² may be a substituted or unsubstituted heteroaryl group having 4 to 30 ring carbon atoms (e.g., 5 to 35 total ring atoms). In an implementation, the heteroaryl group may include, e.g., a benzothiazolyl group, a thiophenyl group, a thienothiophenyl group, a thienothienothiophenyl group, a benzothiophenyl group, a benzofuryl group, a dibenzothiophenyl group, a dibenzofuryl group, an N-carbazolyl group, an N-heteroarylcarbazolyl group, an N-alkylcarbazolyl group, a phenoxazyl group, a phenothiazyl group, a pyridyl group, a pyrimidyl group, a trazinyl group, a quinolinyl group, a quinoxalyl group, or the like.

In the compound for an organic EL device according to an embodiment, a carbazole coupling compound (with high hole transporting properties) may be substituted with an indolocarbazolyl group (with high electron tolerance). Thus, the electron tolerance of the organic EL device may be improved, and the high efficiency and the long life of the organic EL device may be realized. In addition, the driving voltage thereof may be decreased.

The compound for an organic EL device according to an embodiment (e.g., represented by Formula (1)) may be one of the following Compounds 1 to 119.

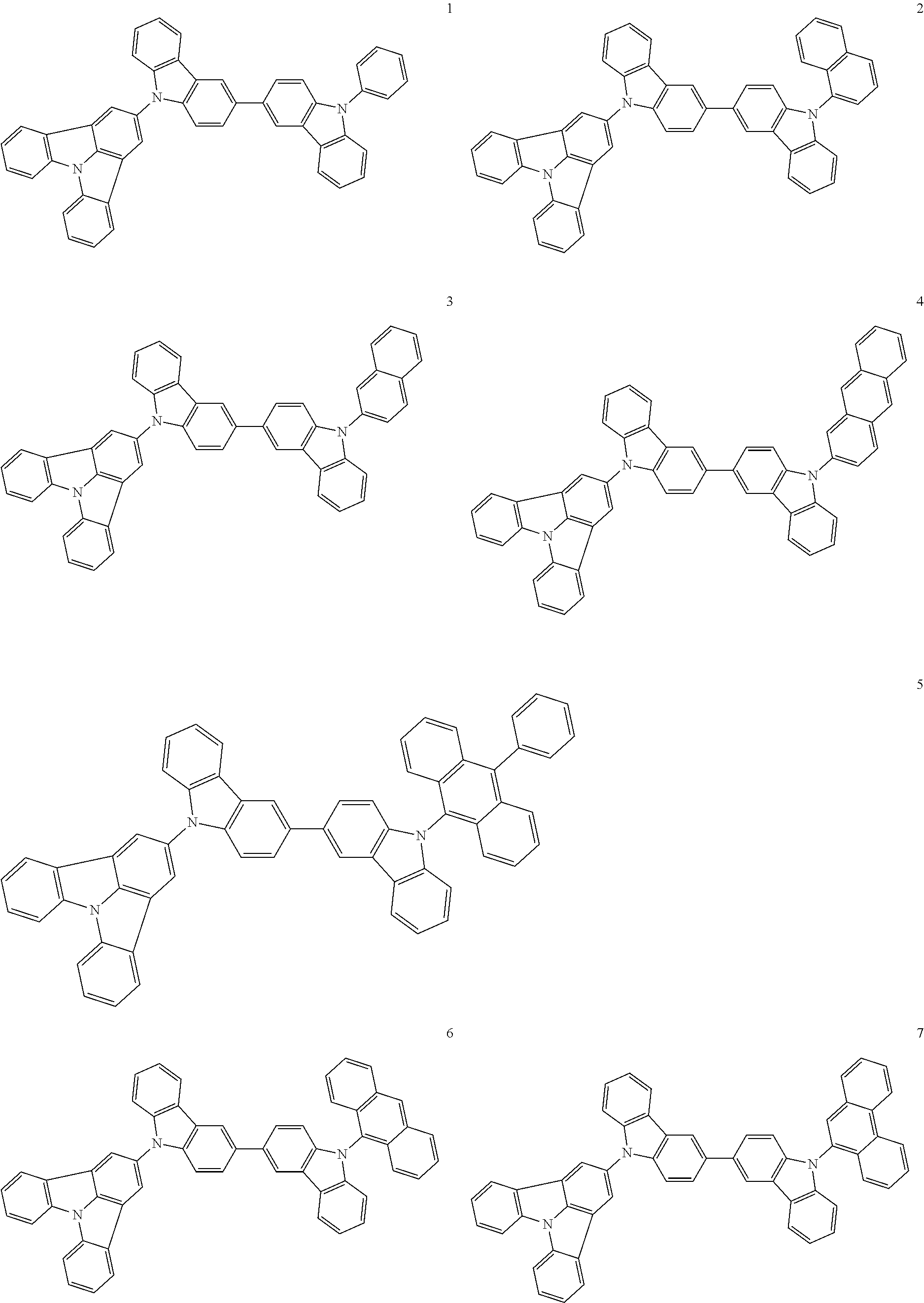

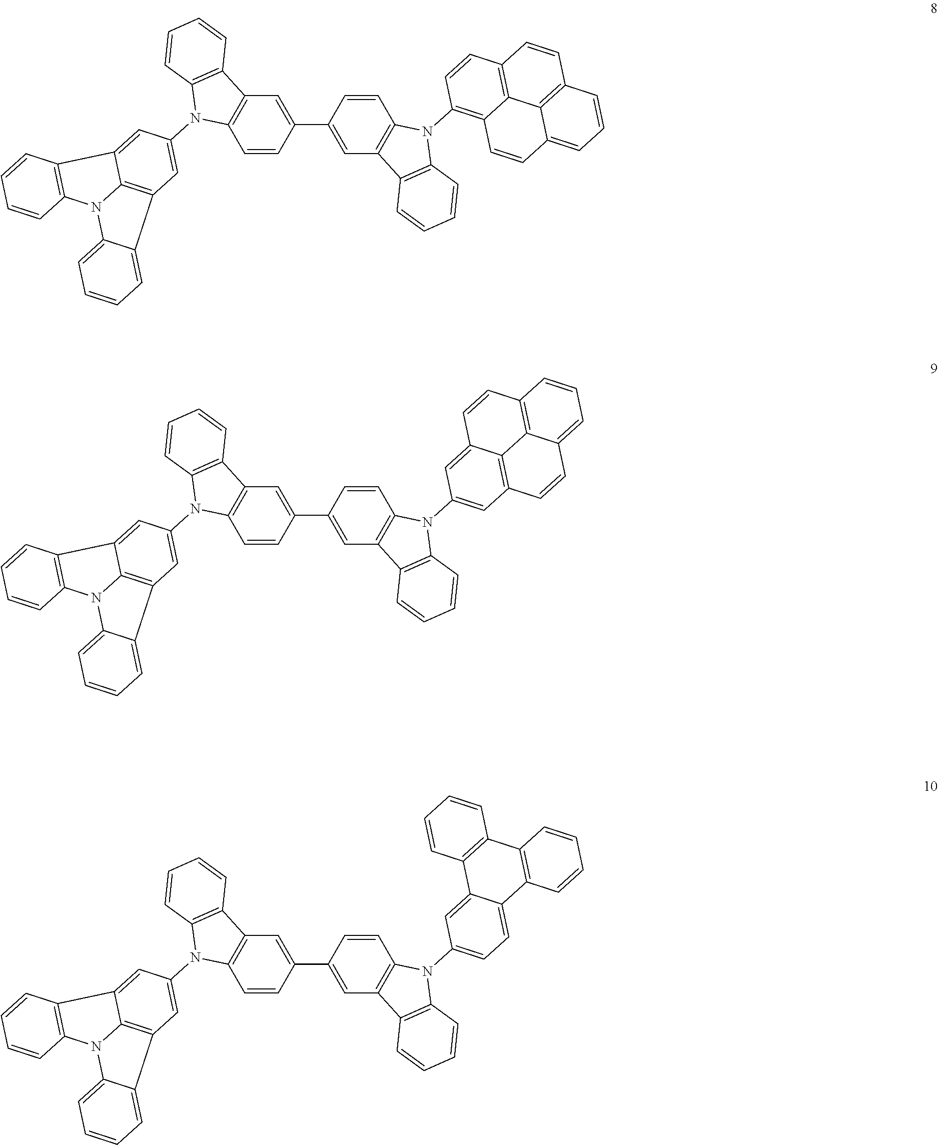 [SMILES: c1cc2ccc3ccc(-n4c5ccccc5c5cc(-c6ccc7c(c6)c6ccccc6n7-c6cc7c8ccccc8n8c9ccccc9c(c6)c78)ccc54)c4ccc(c1)c2c34 ; c1cc2ccc3cc(-n4c5ccccc5c5cc(-c6ccc7c(c6)c6ccccc6n7-c6cc7c8ccccc8n8c9ccccc9c(c6)c78)ccc54)cc4ccc(c1)c2c34 ; c1ccc2c(c1)c1ccccc1c1cc(-n3c4ccccc4c4cc(-c5ccc6c(c5)c5ccccc5n6-c5cc6c7ccccc7n7c8ccccc8c(c5)c67)ccc43)ccc21]

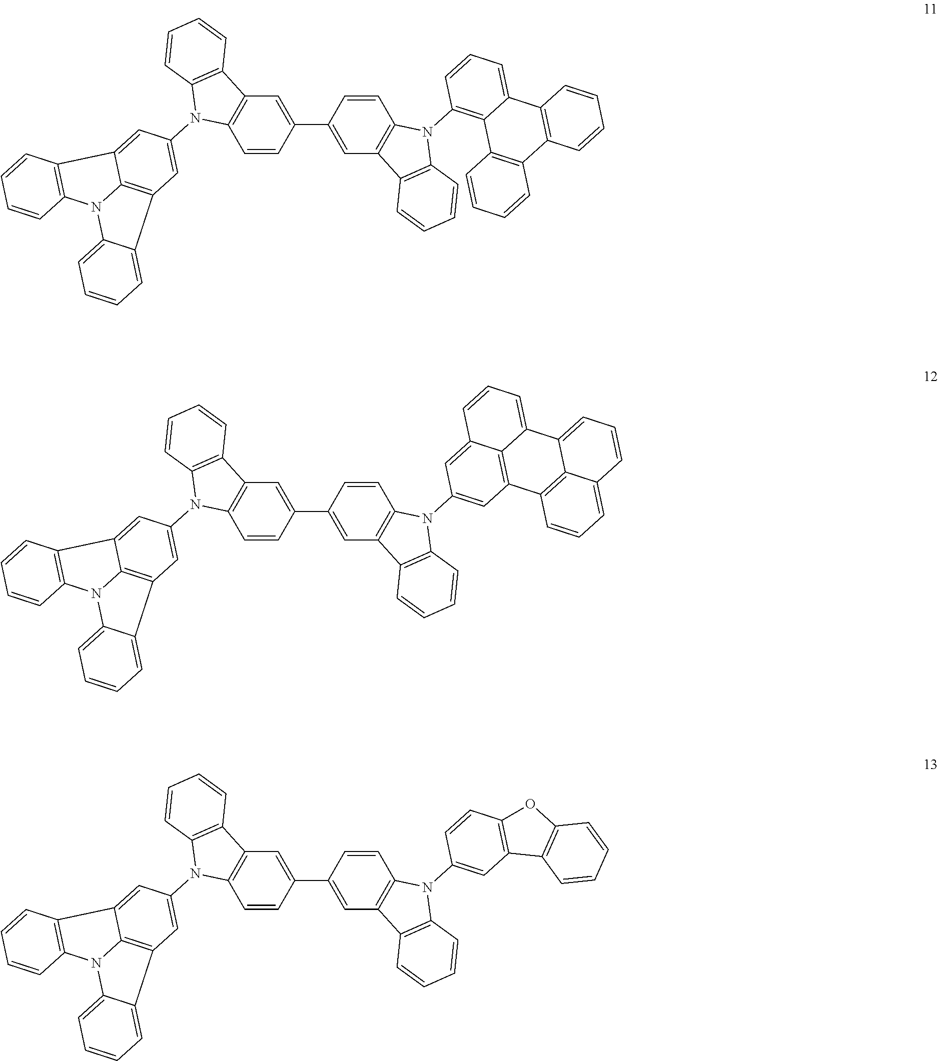 [SMILES: c1ccc2c(c1)c1ccccc1c1c(-n3c4ccccc4c4cc(-c5ccc6c(c5)c5ccccc5n6-c5cc6c7ccccc7n7c8ccccc8c(c5)c67)ccc43)cccc21 ; c1cc2cccc3c4cc(-n5c6ccccc6c6cc(-c7ccc8c(c7)c7ccccc7n8-c7cc8c9ccccc9n9c%10ccccc%10c(c7)c89)ccc65)cc5cccc(c(c1)c23)c54 ; c1ccc2c(c1)oc1ccc(-n3c4ccccc4c4cc(-c5ccc6c(c5)c5ccccc5n6-c5cc6c7ccccc7n7c8ccccc8c(c5)c67)ccc43)cc12]

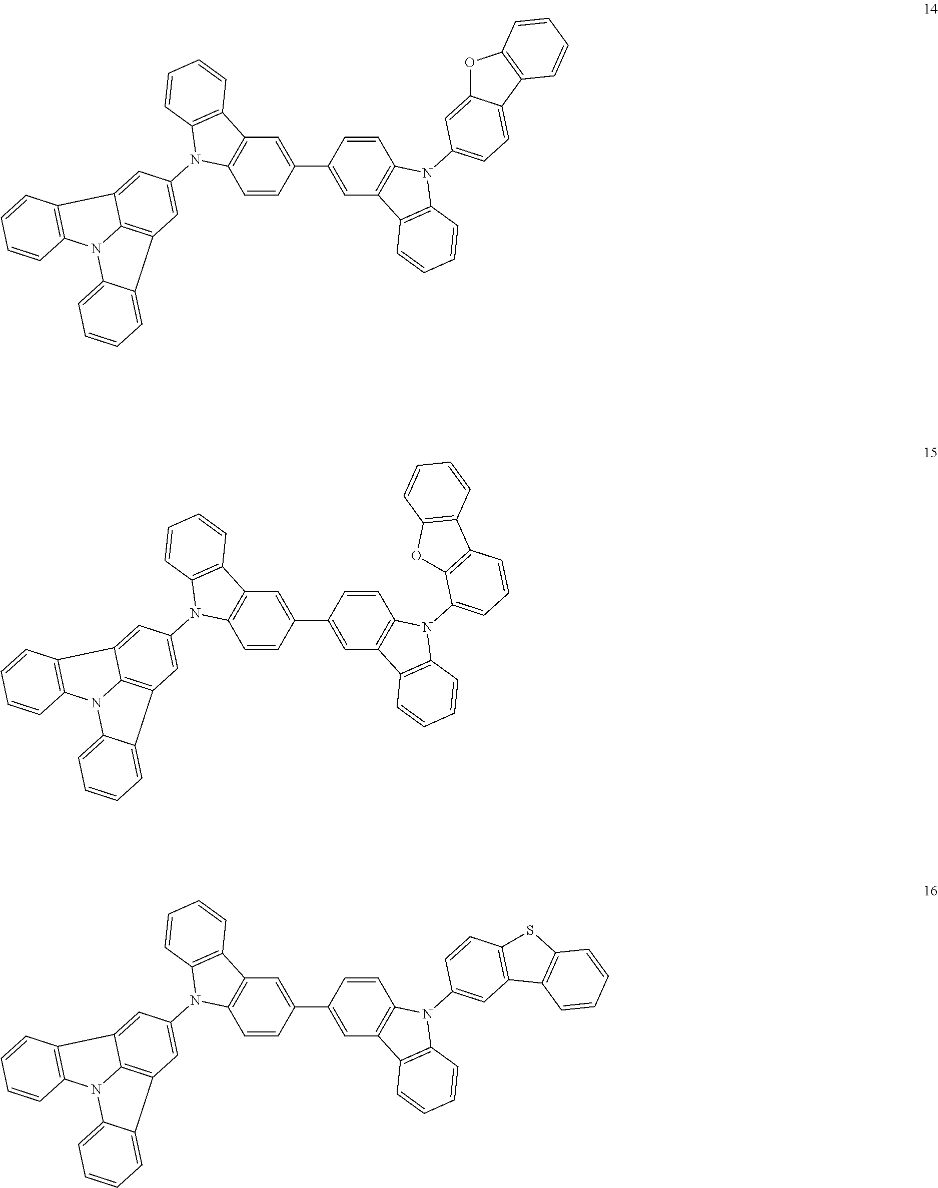 [SMILES: c1ccc2c(c1)oc1cc(-n3c4ccccc4c4cc(-c5ccc6c(c5)c5ccccc5n6-c5cc6c7ccccc7n7c8ccccc8c(c5)c67)ccc43)ccc12 ; c1ccc2c(c1)oc1c(-n3c4ccccc4c4cc(-c5ccc6c(c5)c5ccccc5n6-c5cc6c7ccccc7n7c8ccccc8c(c5)c67)ccc43)cccc12 ; c1ccc2c(c1)sc1ccc(-n3c4ccccc4c4cc(-c5ccc6c(c5)c5ccccc5n6-c5cc6c7ccccc7n7c8ccccc8c(c5)c67)ccc43)cc12]

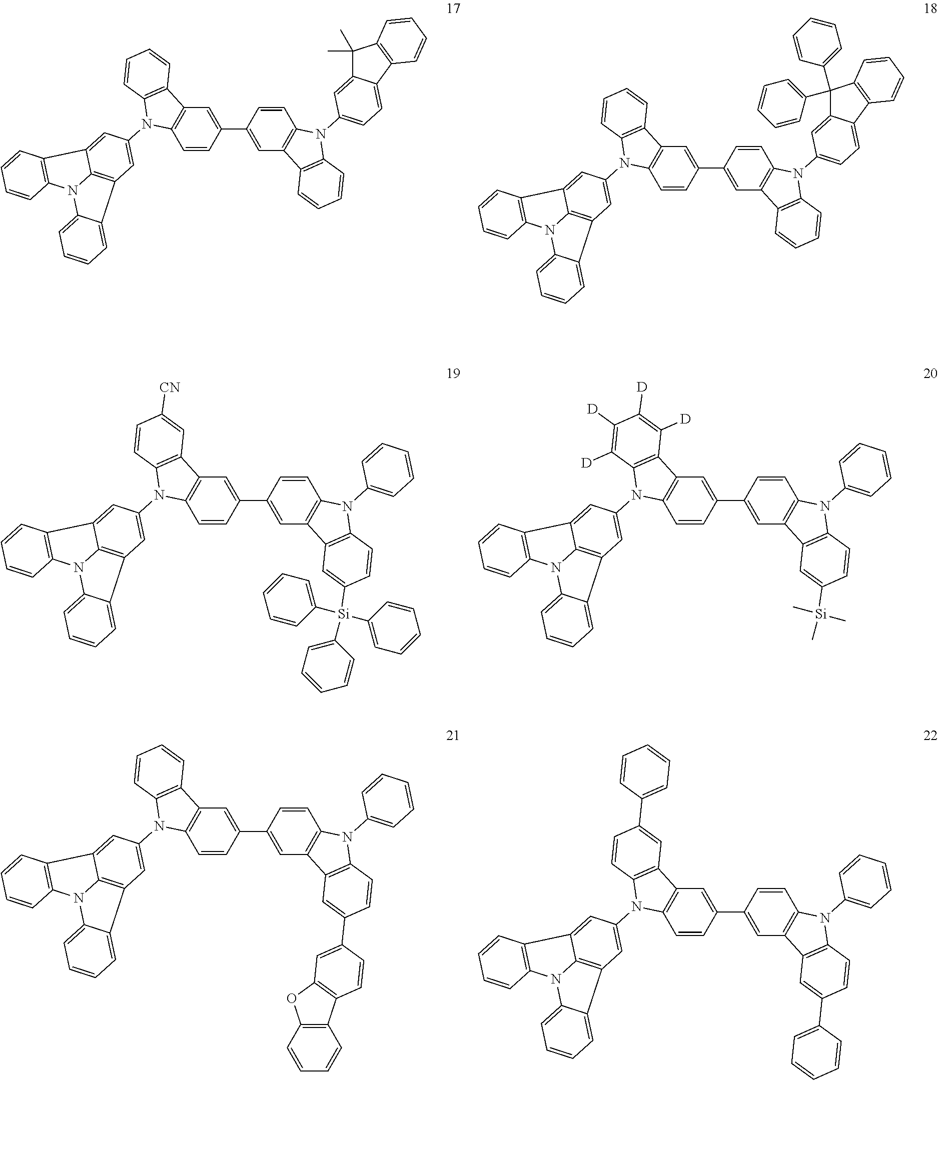

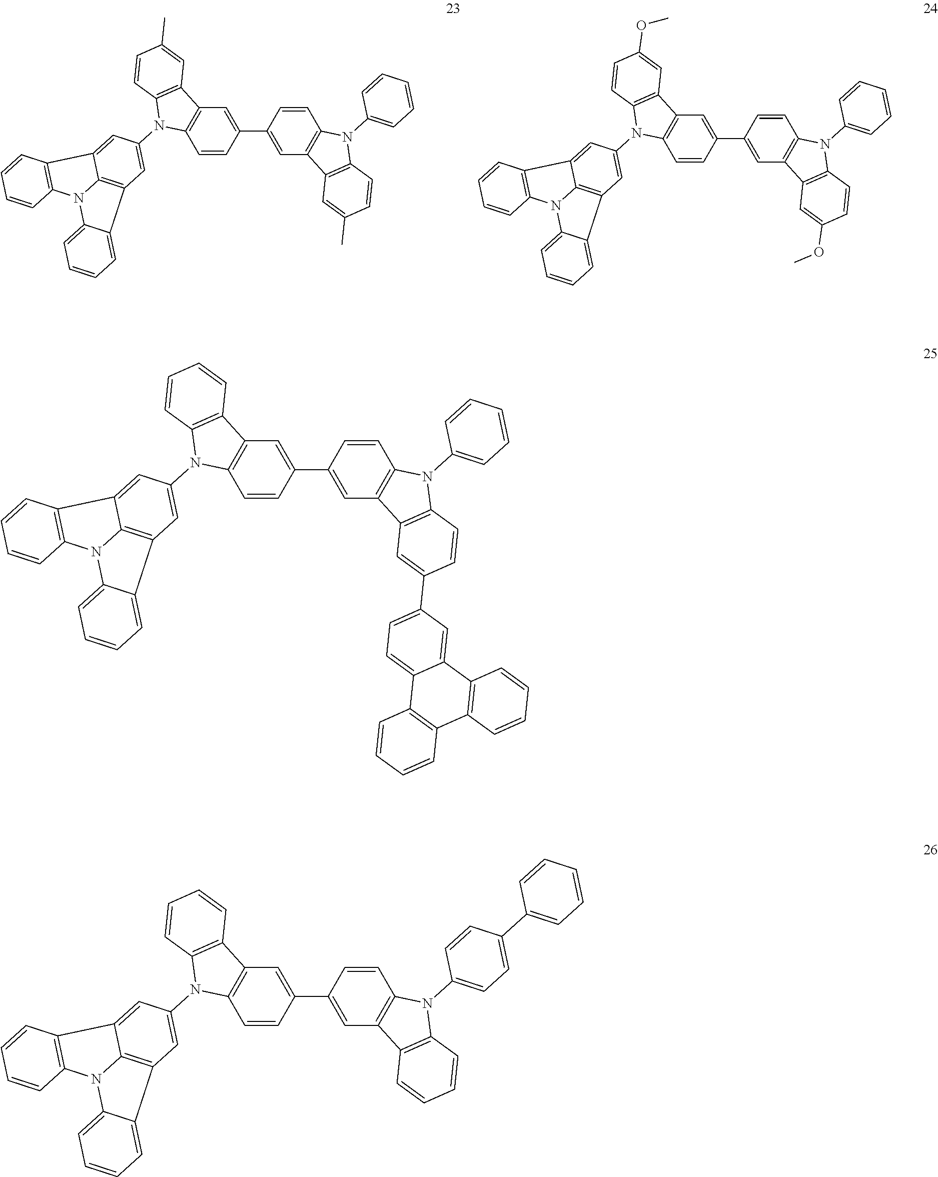 [SMILES: Cc1ccc2c(c1)c1cc(-c3ccc4c(c3)c3cc(C)ccc3n4-c3cc4c5ccccc5n5c6ccccc6c(c3)c45)ccc1n2-c1ccccc1 ; COc1ccc2c(c1)c1cc(-c3ccc4c(c3)c3cc(OC)ccc3n4-c3cc4c5ccccc5n5c6ccccc6c(c3)c45)ccc1n2-c1ccccc1 ; c1ccc(-n2c3ccc(-c4ccc5c6ccccc6c6ccccc6c5c4)cc3c3cc(-c4ccc5c(c4)c4ccccc4n5-c4cc5c6ccccc6n6c7ccccc7c(c4)c56)ccc32)cc1 ; c1ccc(-c2ccc(-n3c4ccccc4c4cc(-c5ccc6c(c5)c5ccccc5n6-c5cc6c7ccccc7n7c8ccccc8c(c5)c67)ccc43)cc2)cc1]

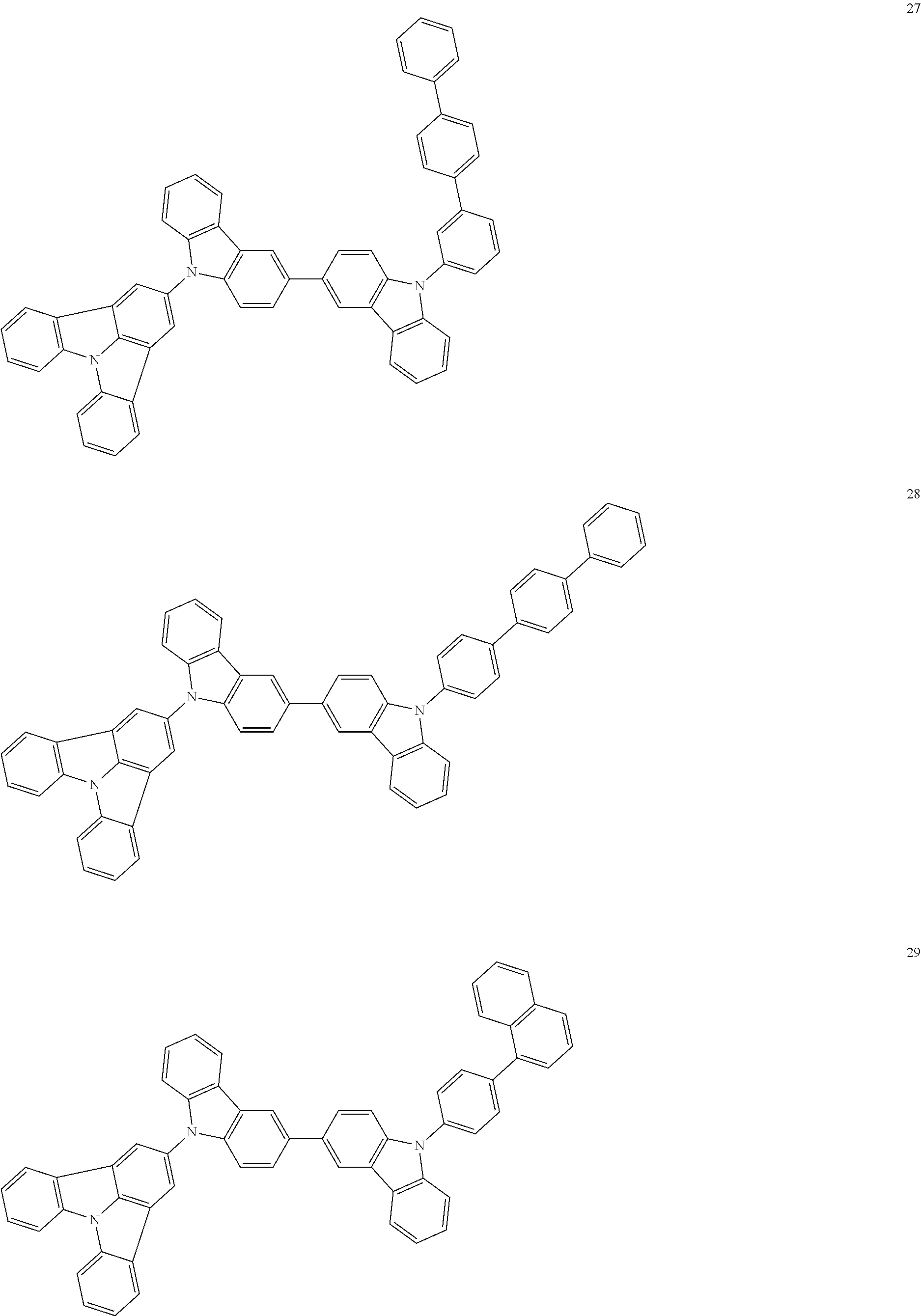 [SMILES: c1ccc(-c2ccc(-c3cccc(-n4c5ccccc5c5cc(-c6ccc7c(c6)c6ccccc6n7-c6cc7c8ccccc8n8c9ccccc9c(c6)c78)ccc54)c3)cc2)cc1 ; c1ccc(-c2ccc(-c3ccc(-n4c5ccccc5c5cc(-c6ccc7c(c6)c6ccccc6n7-c6cc7c8ccccc8n8c9ccccc9c(c6)c78)ccc54)cc3)cc2)cc1 ; c1ccc2c(-c3ccc(-n4c5ccccc5c5cc(-c6ccc7c(c6)c6ccccc6n7-c6cc7c8ccccc8n8c9ccccc9c(c6)c78)ccc54)cc3)cccc2c1]

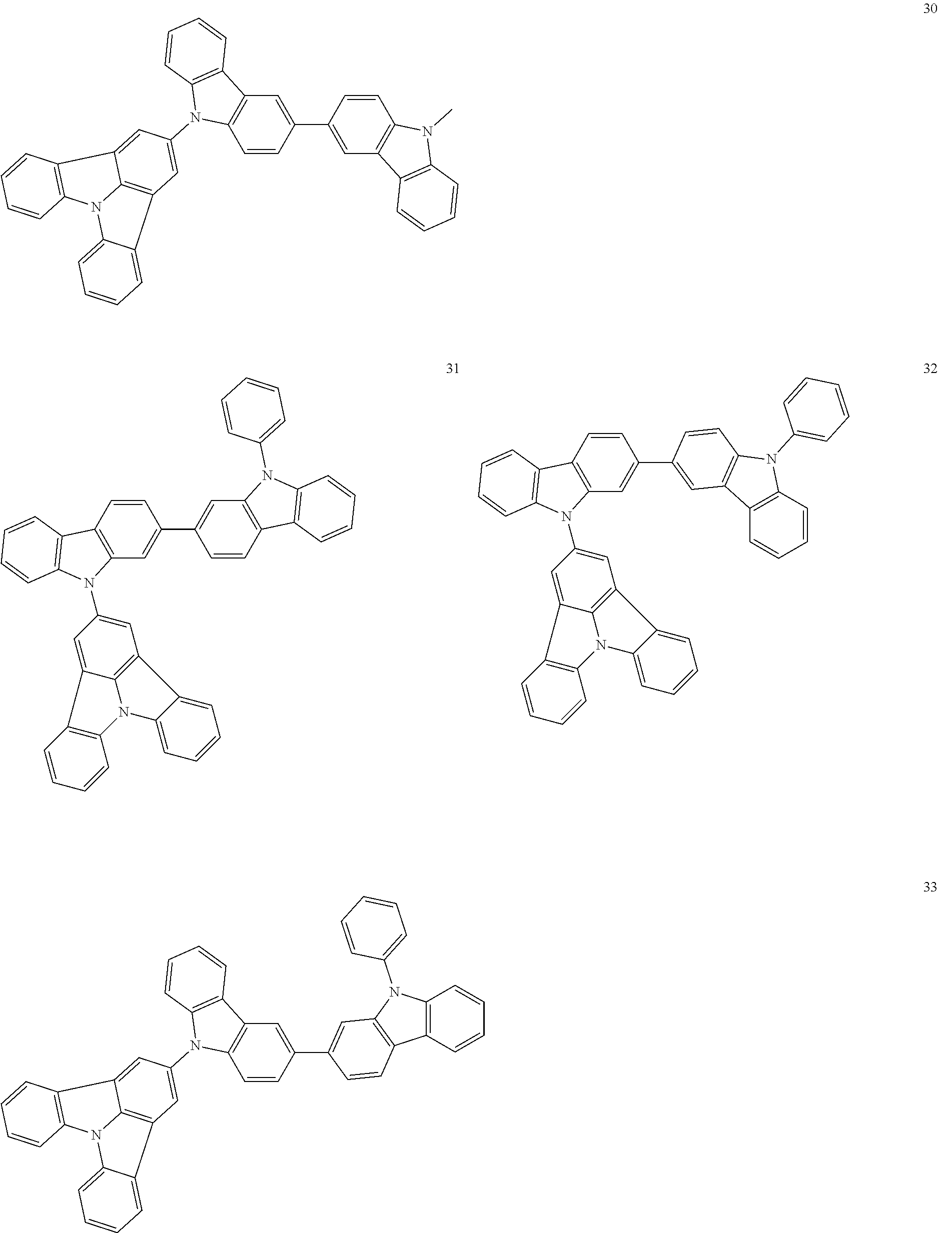 [SMILES: Cn1c2ccccc2c2cc(-c3ccc4c(c3)c3ccccc3n4-c3cc4c5ccccc5n5c6ccccc6c(c3)c45)ccc21 ; c1ccc(-n2c3ccccc3c3ccc(-c4ccc5c6ccccc6n(-c6cc7c8ccccc8n8c9ccccc9c(c6)c78)c5c4)cc32)cc1 ; c1ccc(-n2c3ccccc3c3cc(-c4ccc5c6ccccc6n(-c6cc7c8ccccc8n8c9ccccc9c(c6)c78)c5c4)ccc32)cc1 ; c1ccc(-n2c3ccccc3c3ccc(-c4ccc5c(c4)c4ccccc4n5-c4cc5c6ccccc6n6c7ccccc7c(c4)c56)cc32)cc1]

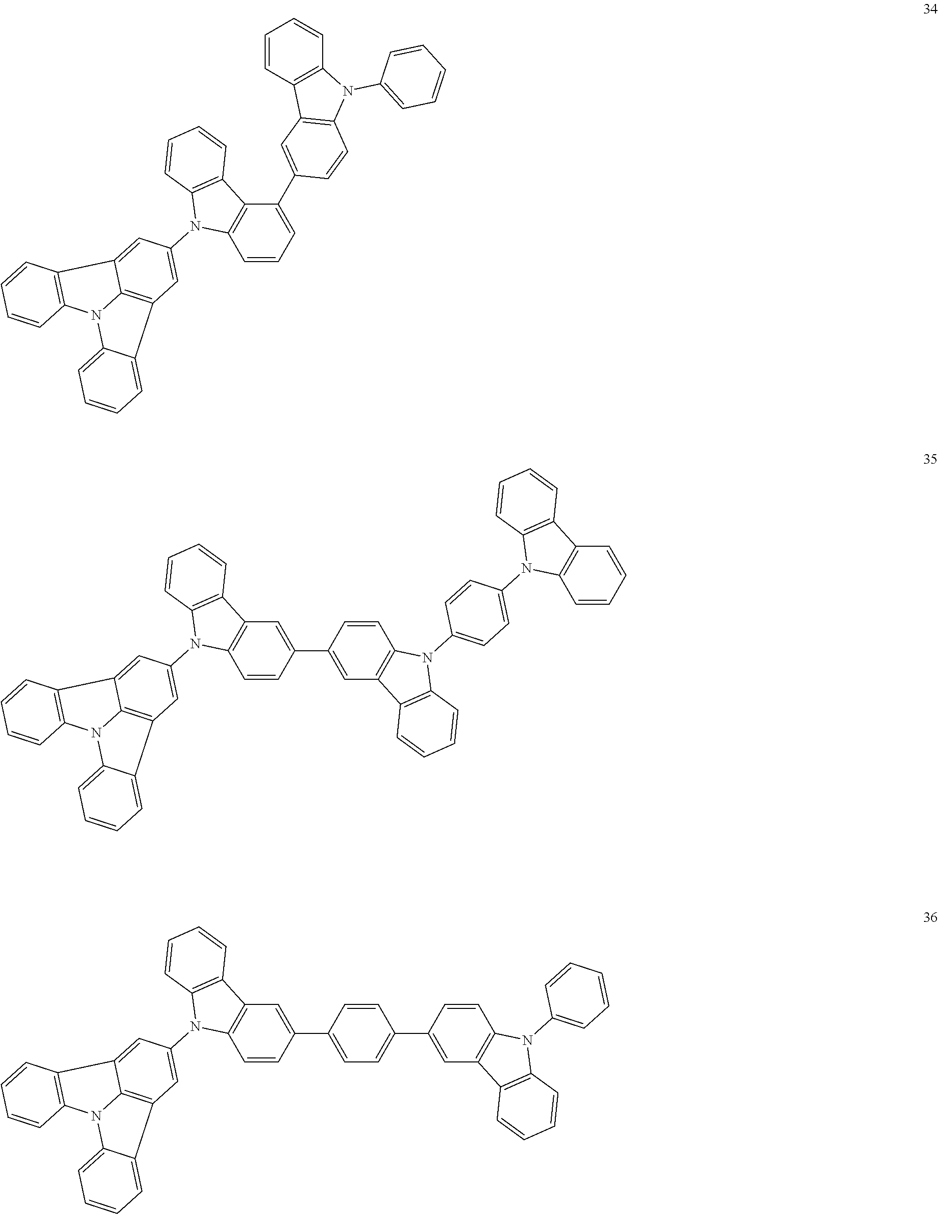 [SMILES: c1ccc(-n2c3ccccc3c3cc(-c4cccc5c4c4ccccc4n5-c4cc5c6ccccc6n6c7ccccc7c(c4)c56)ccc32)cc1 ; c1ccc2c(c1)c1ccccc1n2-c1ccc(-n2c3ccccc3c3cc(-c4ccc5c(c4)c4ccccc4n5-c4cc5c6ccccc6n6c7ccccc7c(c4)c56)ccc32)cc1 ; c1ccc(-n2c3ccccc3c3cc(-c4ccc(-c5ccc6c(c5)c5ccccc5n6-c5cc6c7ccccc7n7c8ccccc8c(c5)c67)cc4)ccc32)cc1]

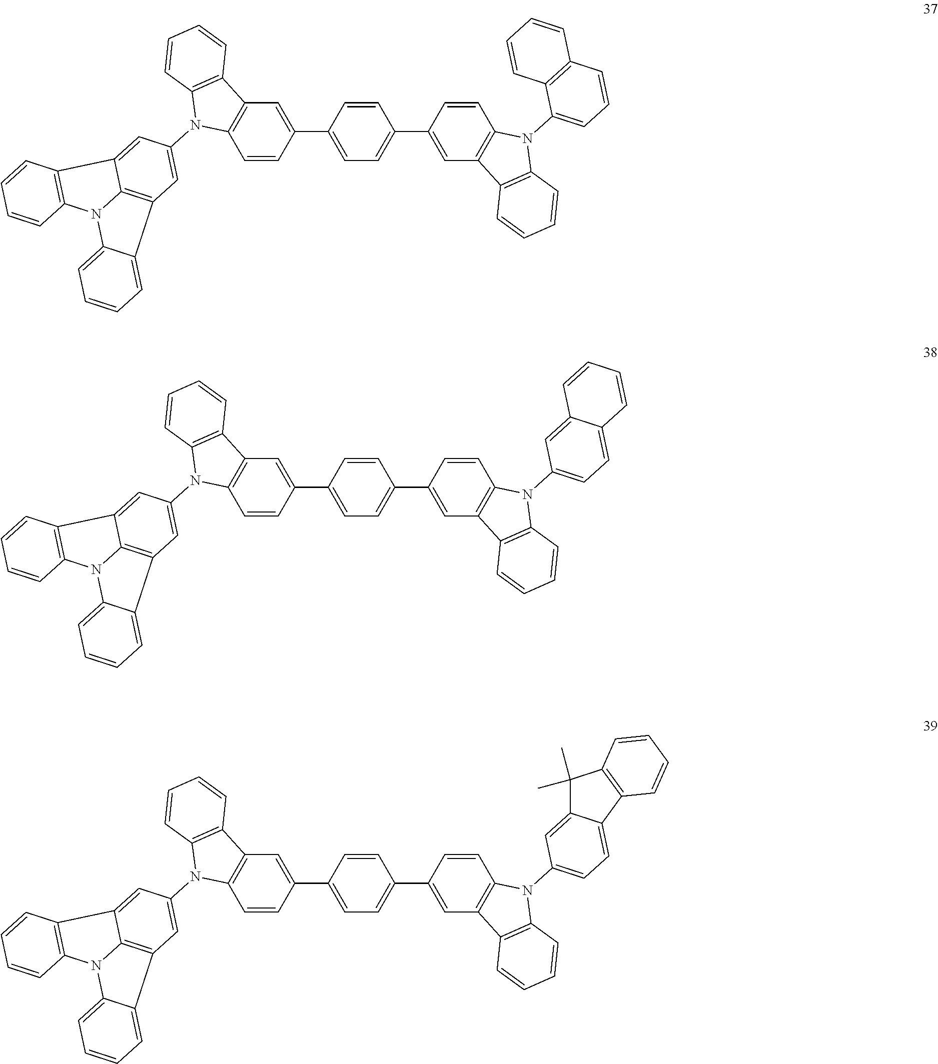 [SMILES: c1ccc2c(-n3c4ccccc4c4cc(-c5ccc(-c6ccc7c(c6)c6ccccc6n7-c6cc7c8ccccc8n8c9ccccc9c(c6)c78)cc5)ccc43)cccc2c1 ; c1ccc2cc(-n3c4ccccc4c4cc(-c5ccc(-c6ccc7c(c6)c6ccccc6n7-c6cc7c8ccccc8n8c9ccccc9c(c6)c78)cc5)ccc43)ccc2c1 ; CC1(C)c2ccccc2-c2ccc(-n3c4ccccc4c4cc(-c5ccc(-c6ccc7c(c6)c6ccccc6n7-c6cc7c8ccccc8n8c9ccccc9c(c6)c78)cc5)ccc43)cc21]

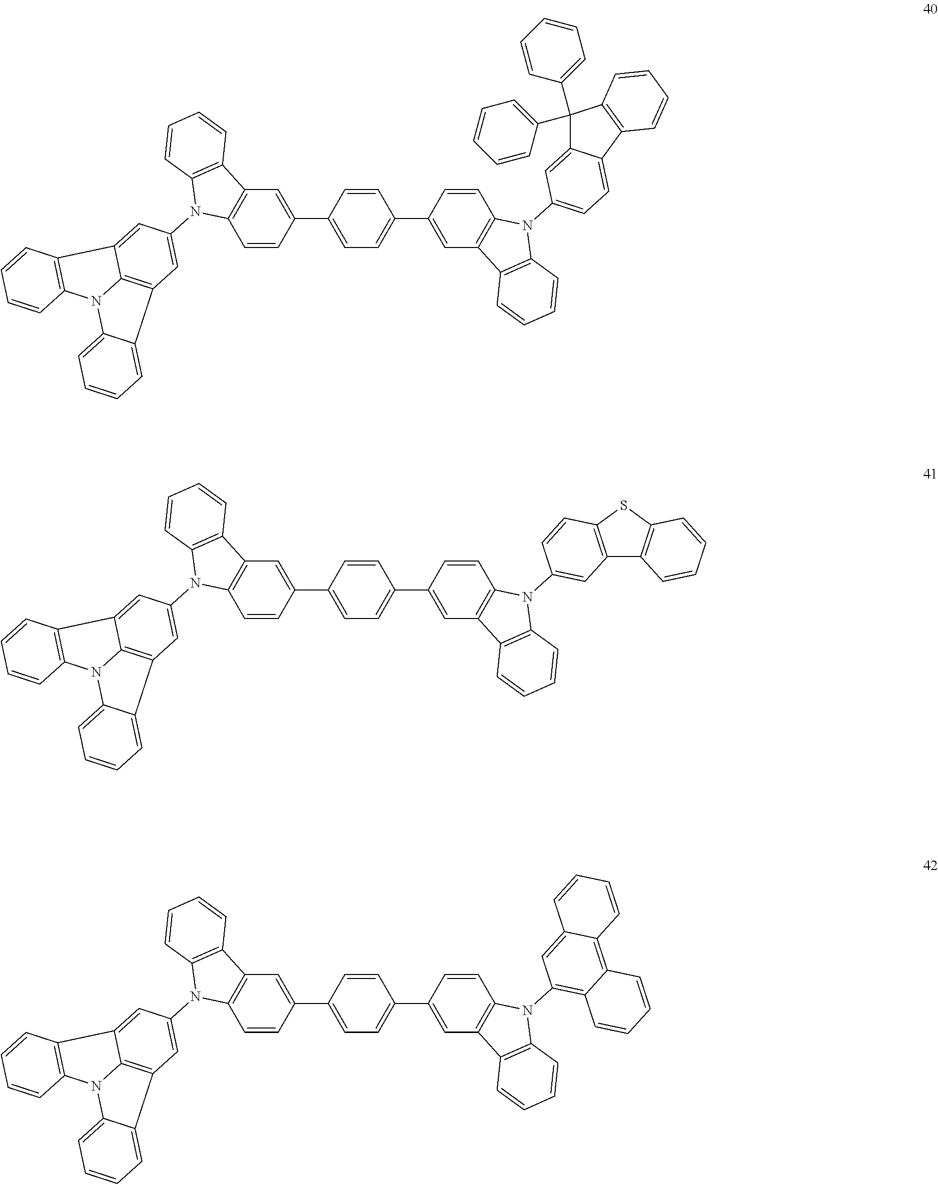 [SMILES: c1ccc(C2(c3ccccc3)c3ccccc3-c3ccc(-n4c5ccccc5c5cc(-c6ccc(-c7ccc8c(c7)c7ccccc7n8-c7cc8c9ccccc9n9c%10ccccc%10c(c7)c89)cc6)ccc54)cc32)cc1 ; c1ccc2c(c1)sc1ccc(-n3c4ccccc4c4cc(-c5ccc(-c6ccc7c(c6)c6ccccc6n7-c6cc7c8ccccc8n8c9ccccc9c(c6)c78)cc5)ccc43)cc12 ; c1ccc2c(c1)cc(-n1c3ccccc3c3cc(-c4ccc(-c5ccc6c(c5)c5ccccc5n6-c5cc6c7ccccc7n7c8ccccc8c(c5)c67)cc4)ccc31)c1ccccc12]

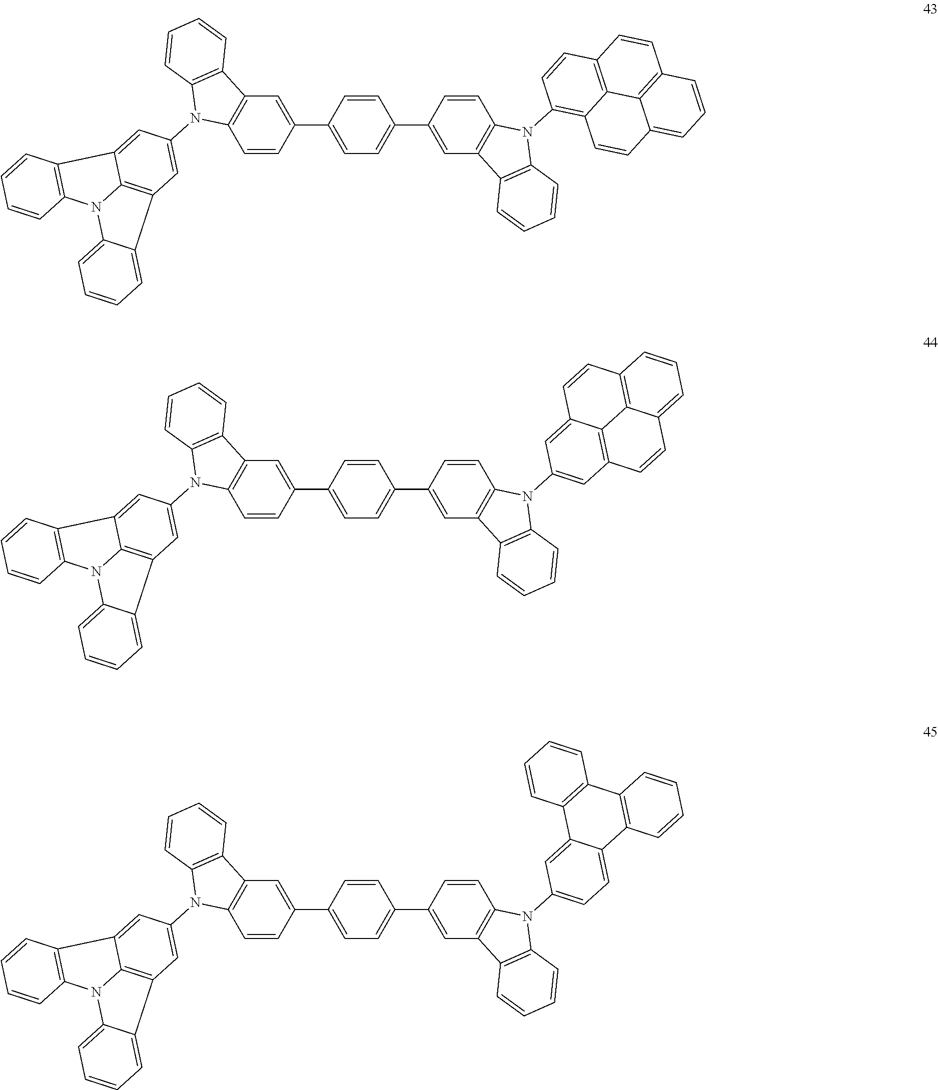 [SMILES: c1cc2ccc3ccc(-n4c5ccccc5c5cc(-c6ccc(-c7ccc8c(c7)c7ccccc7n8-c7cc8c9ccccc9n9c%10ccccc%10c(c7)c89)cc6)ccc54)c4ccc(c1)c2c34 ; c1cc2ccc3cc(-n4c5ccccc5c5cc(-c6ccc(-c7ccc8c(c7)c7ccccc7n8-c7cc8c9ccccc9n9c%10ccccc%10c(c7)c89)cc6)ccc54)cc4ccc(c1)c2c34 ; c1ccc2c(c1)c1ccccc1c1cc(-n3c4ccccc4c4cc(-c5ccc(-c6ccc7c(c6)c6ccccc6n7-c6cc7c8ccccc8n8c9ccccc9c(c6)c78)cc5)ccc43)ccc21]

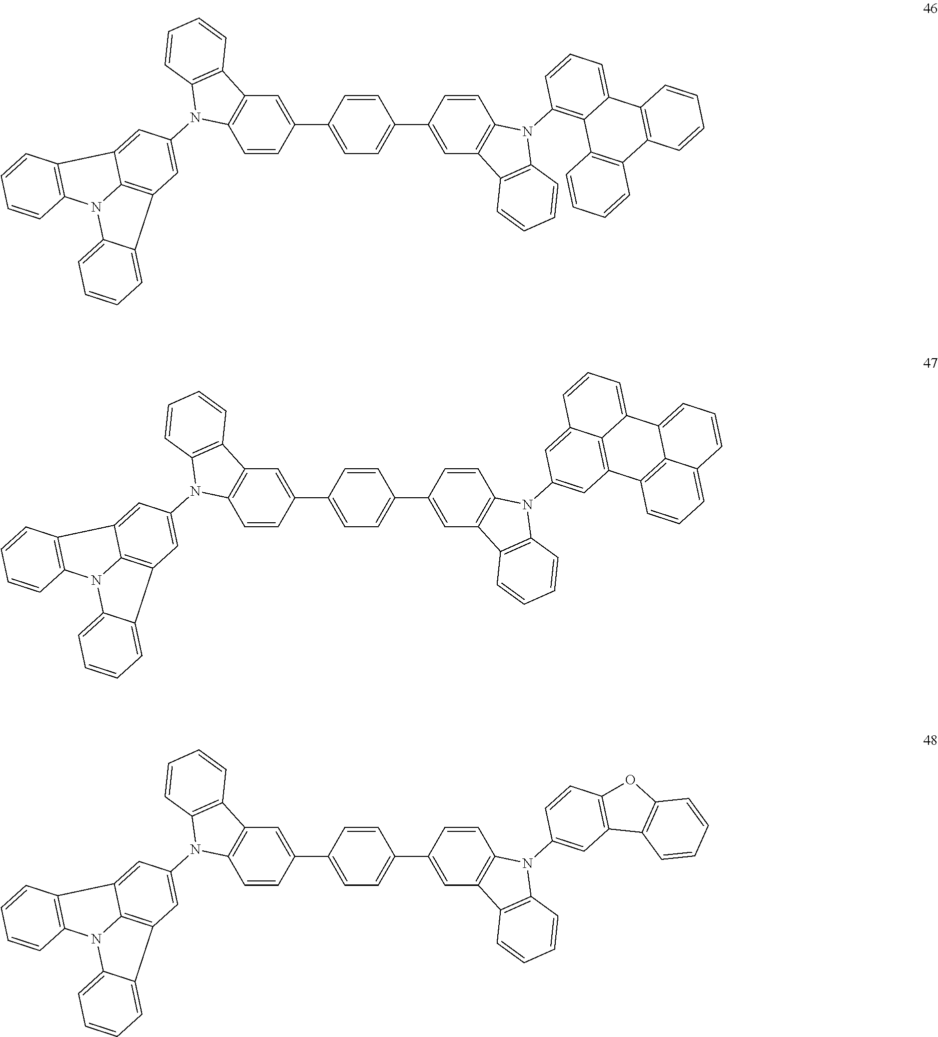 [SMILES: c1ccc2c(c1)c1ccccc1c1c(-n3c4ccccc4c4cc(-c5ccc(-c6ccc7c(c6)c6ccccc6n7-c6cc7c8ccccc8n8c9ccccc9c(c6)c78)cc5)ccc43)cccc21 ; c1cc2cccc3c4cc(-n5c6ccccc6c6cc(-c7ccc(-c8ccc9c(c8)c8ccccc8n9-c8cc9c%10ccccc%10n%10c%11ccccc%11c(c8)c9%10)cc7)ccc65)cc5cccc(c(c1)c23)c54 ; c1ccc2c(c1)oc1ccc(-n3c4ccccc4c4cc(-c5ccc(-c6ccc7c(c6)c6ccccc6n7-c6cc7c8ccccc8n8c9ccccc9c(c6)c78)cc5)ccc43)cc12]

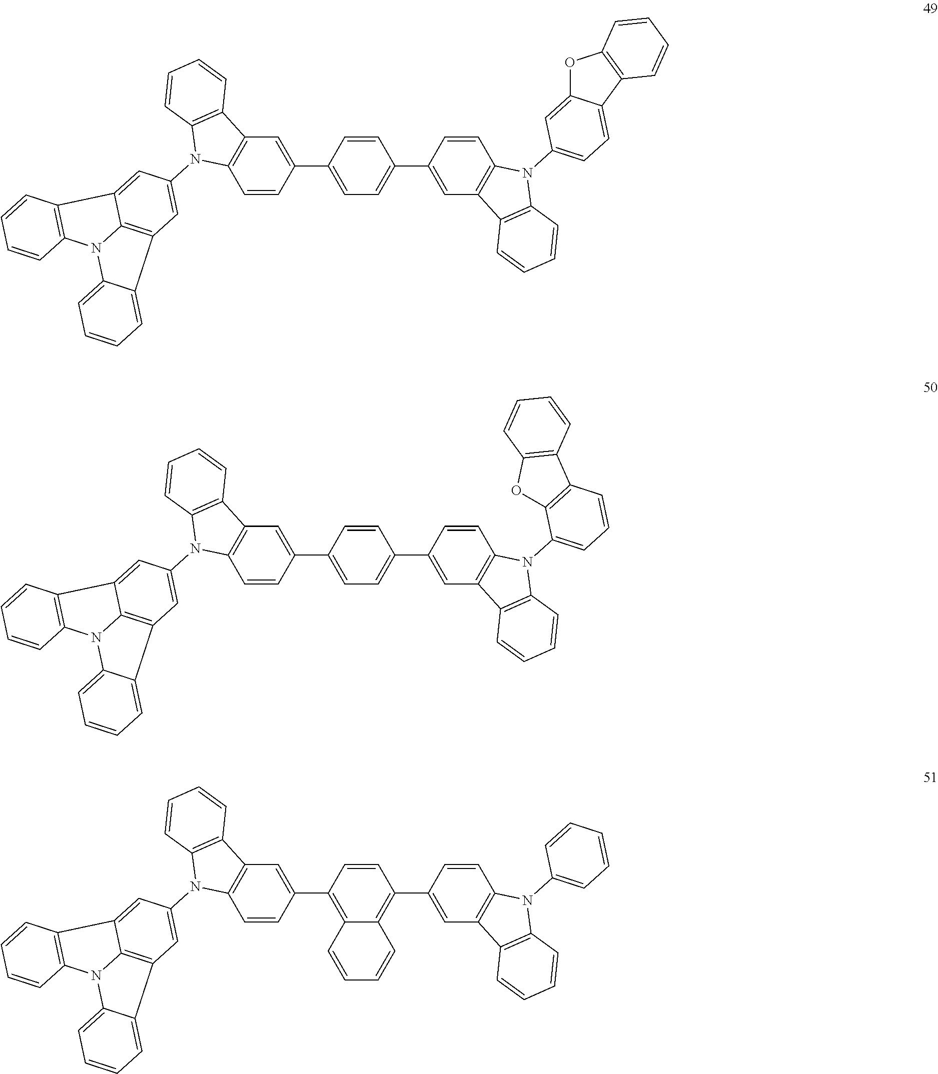 [SMILES: c1ccc2c(c1)oc1cc(-n3c4ccccc4c4cc(-c5ccc(-c6ccc7c(c6)c6ccccc6n7-c6cc7c8ccccc8n8c9ccccc9c(c6)c78)cc5)ccc43)ccc12 ; c1ccc2c(c1)oc1c(-n3c4ccccc4c4cc(-c5ccc(-c6ccc7c(c6)c6ccccc6n7-c6cc7c8ccccc8n8c9ccccc9c(c6)c78)cc5)ccc43)cccc12 ; c1ccc(-n2c3ccccc3c3cc(-c4ccc(-c5ccc6c(c5)c5ccccc5n6-c5cc6c7ccccc7n7c8ccccc8c(c5)c67)c5ccccc45)ccc32)cc1]

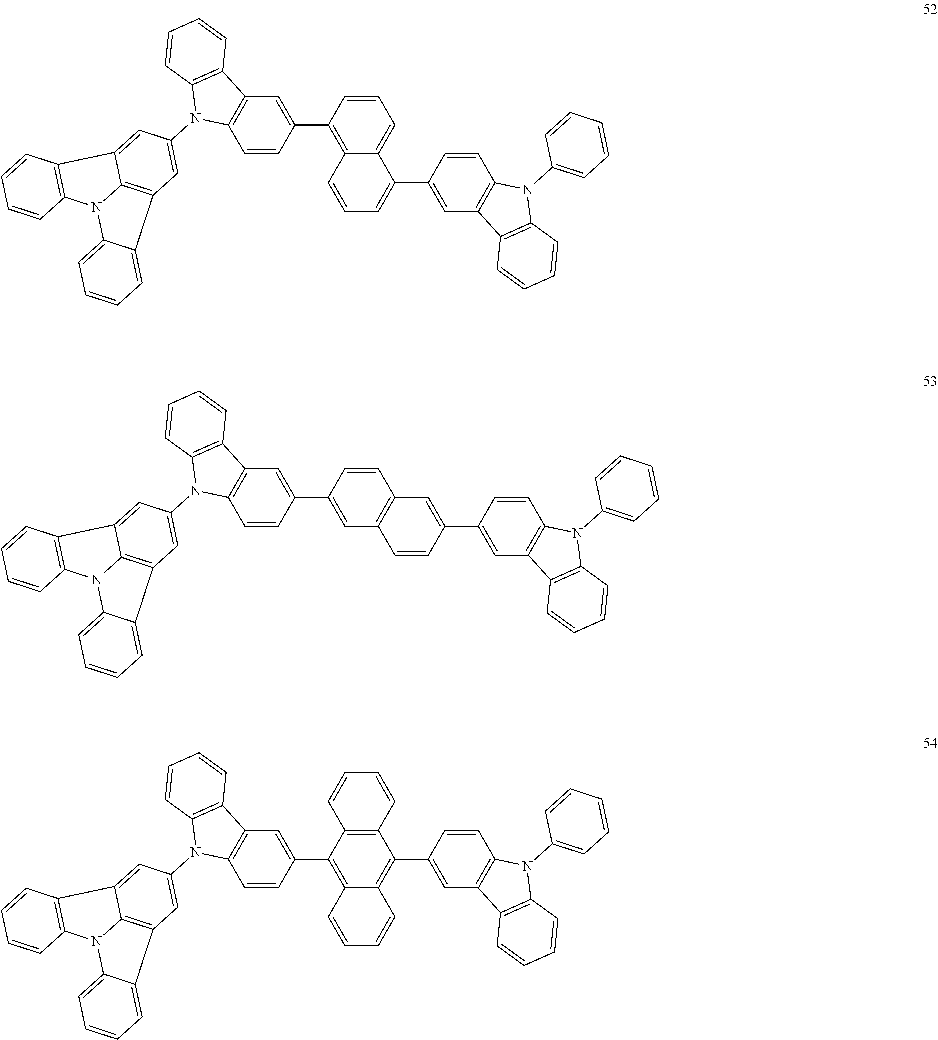 [SMILES: c1ccc(-n2c3ccccc3c3cc(-c4cccc5c(-c6ccc7c(c6)c6ccccc6n7-c6cc7c8ccccc8n8c9ccccc9c(c6)c78)cccc45)ccc32)cc1 ; c1ccc(-n2c3ccccc3c3cc(-c4ccc5cc(-c6ccc7c(c6)c6ccccc6n7-c6cc7c8ccccc8n8c9ccccc9c(c6)c78)ccc5c4)ccc32)cc1 ; c1ccc(-n2c3ccccc3c3cc(-c4c5ccccc5c(-c5ccc6c(c5)c5ccccc5n6-c5cc6c7ccccc7n7c8ccccc8c(c5)c67)c5ccccc45)ccc32)cc1]

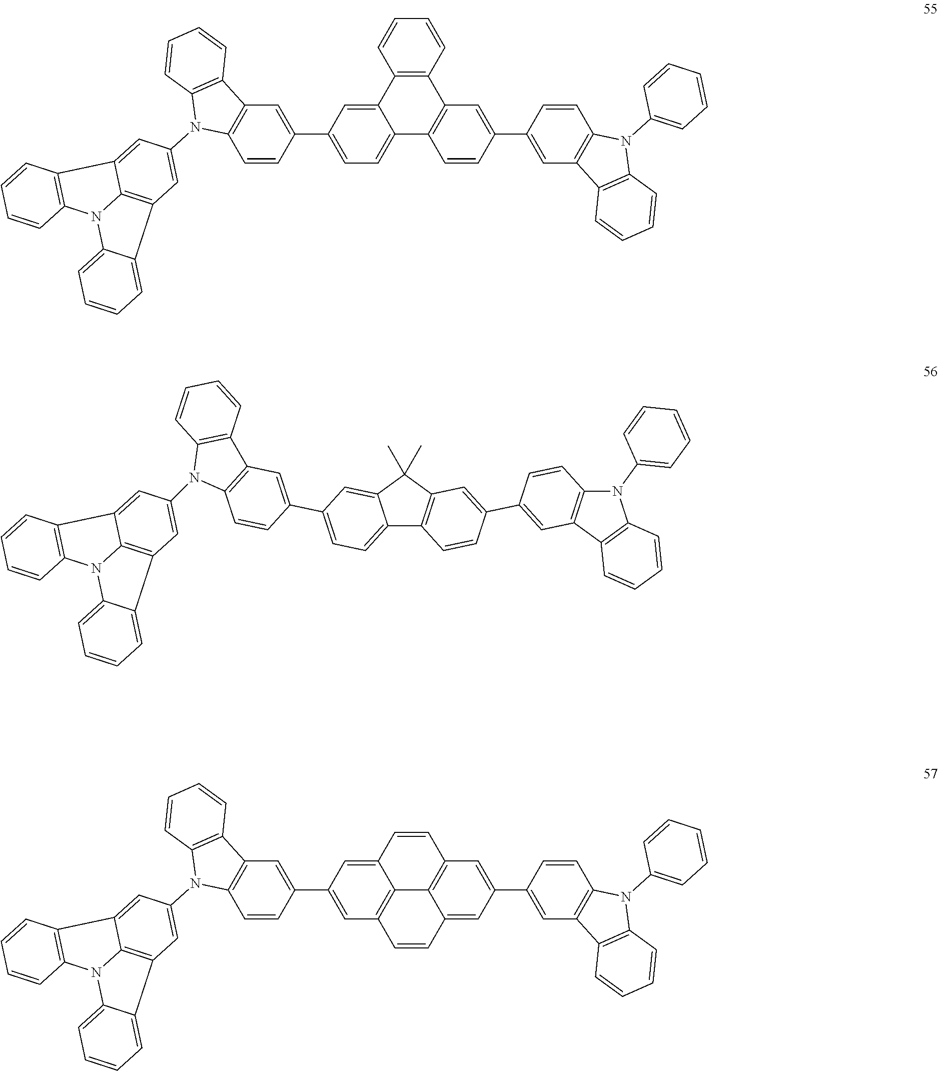 [SMILES: c1ccc(-n2c3ccccc3c3cc(-c4ccc5c6ccc(-c7ccc8c(c7)c7ccccc7n8-c7cc8c9ccccc9n9c%10ccccc%10c(c7)c89)cc6c6ccccc6c5c4)ccc32)cc1 ; CC1(C)c2cc(-c3ccc4c(c3)c3ccccc3n4-c3ccccc3)ccc2-c2ccc(-c3ccc4c(c3)c3ccccc3n4-c3cc4c5ccccc5n5c6ccccc6c(c3)c45)cc21 ; c1ccc(-n2c3ccccc3c3cc(-c4cc5ccc6cc(-c7ccc8c(c7)c7ccccc7n8-c7cc8c9ccccc9n9c%10ccccc%10c(c7)c89)cc7ccc(c4)c5c67)ccc32)cc1]

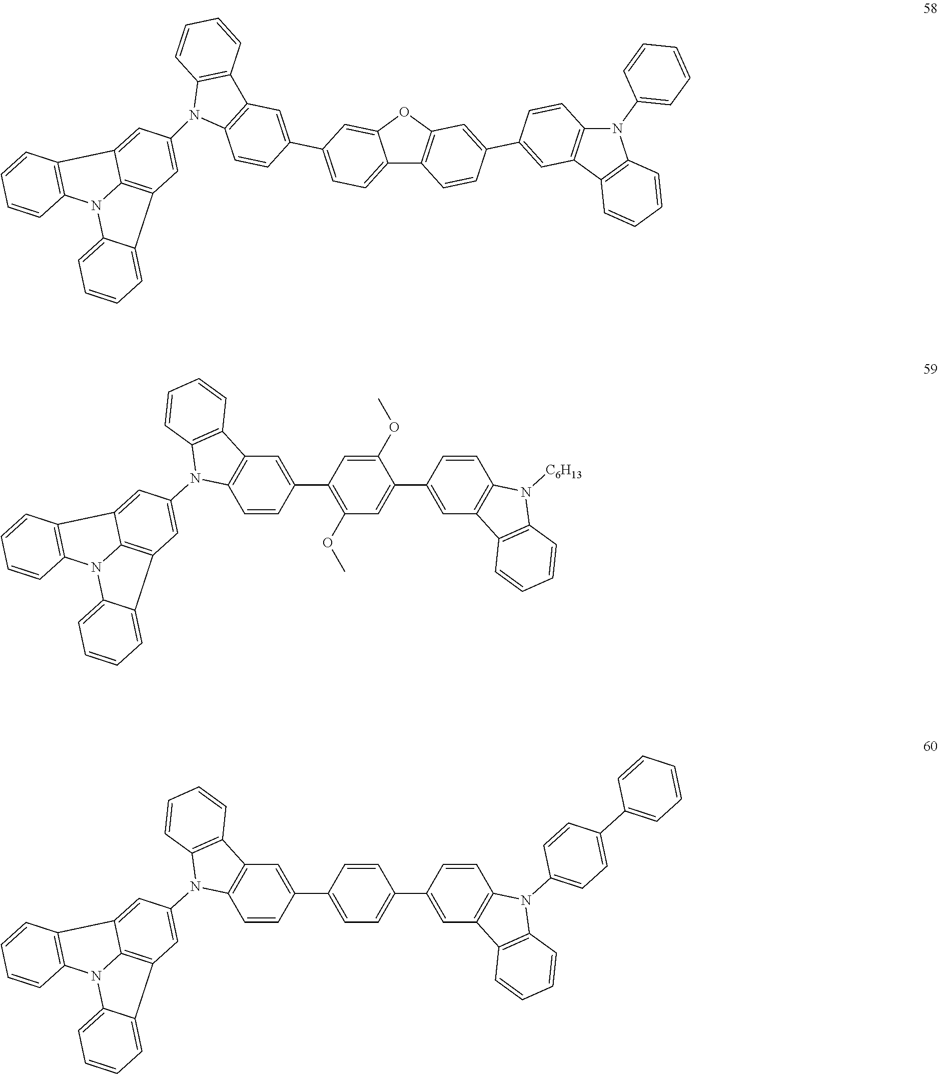

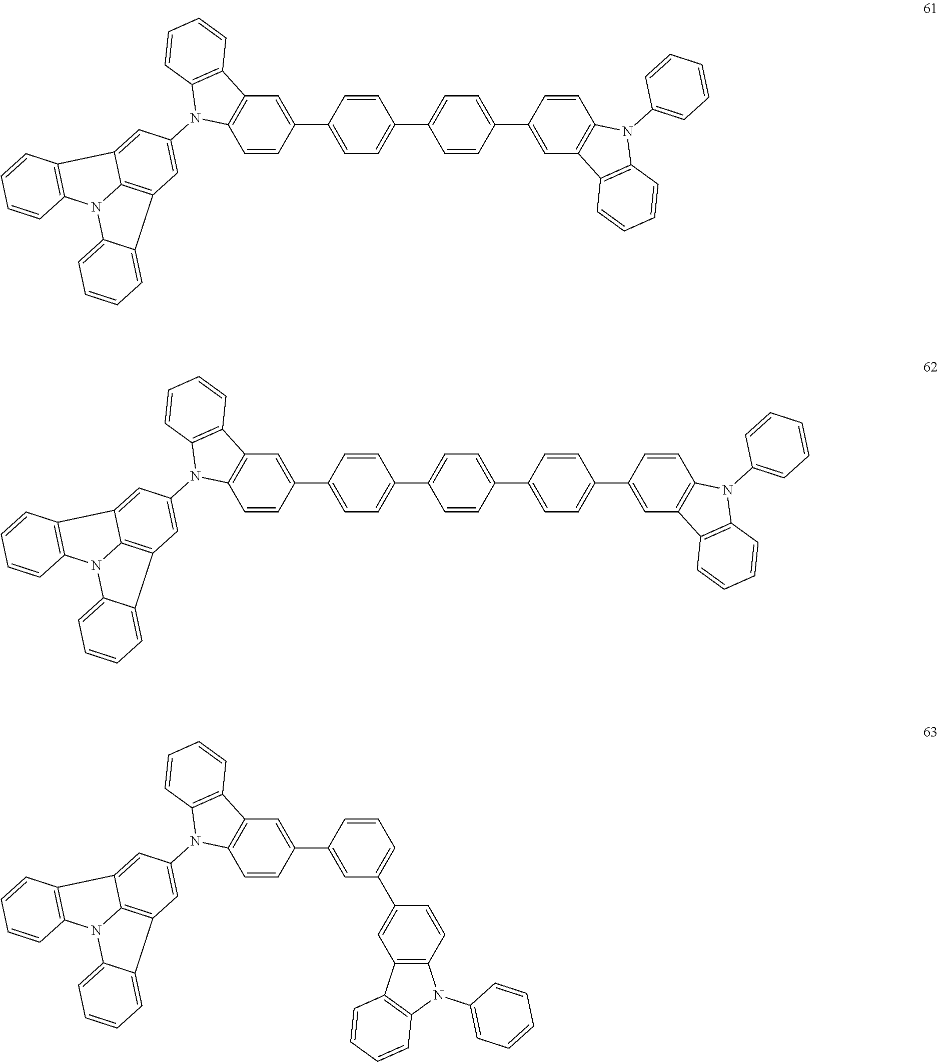 [SMILES: c1ccc(-n2c3ccccc3c3cc(-c4ccc(-c5ccc(-c6ccc7c(c6)c6ccccc6n7-c6cc7c8ccccc8n8c9ccccc9c(c6)c78)cc5)cc4)ccc32)cc1 ; c1ccc(-n2c3ccccc3c3cc(-c4ccc(-c5ccc(-c6ccc(-c7ccc8c(c7)c7ccccc7n8-c7cc8c9ccccc9n9c%10ccccc%10c(c7)c89)cc6)cc5)cc4)ccc32)cc1 ; c1ccc(-n2c3ccccc3c3cc(-c4cccc(-c5ccc6c(c5)c5ccccc5n6-c5cc6c7ccccc7n7c8ccccc8c(c5)c67)c4)ccc32)cc1]

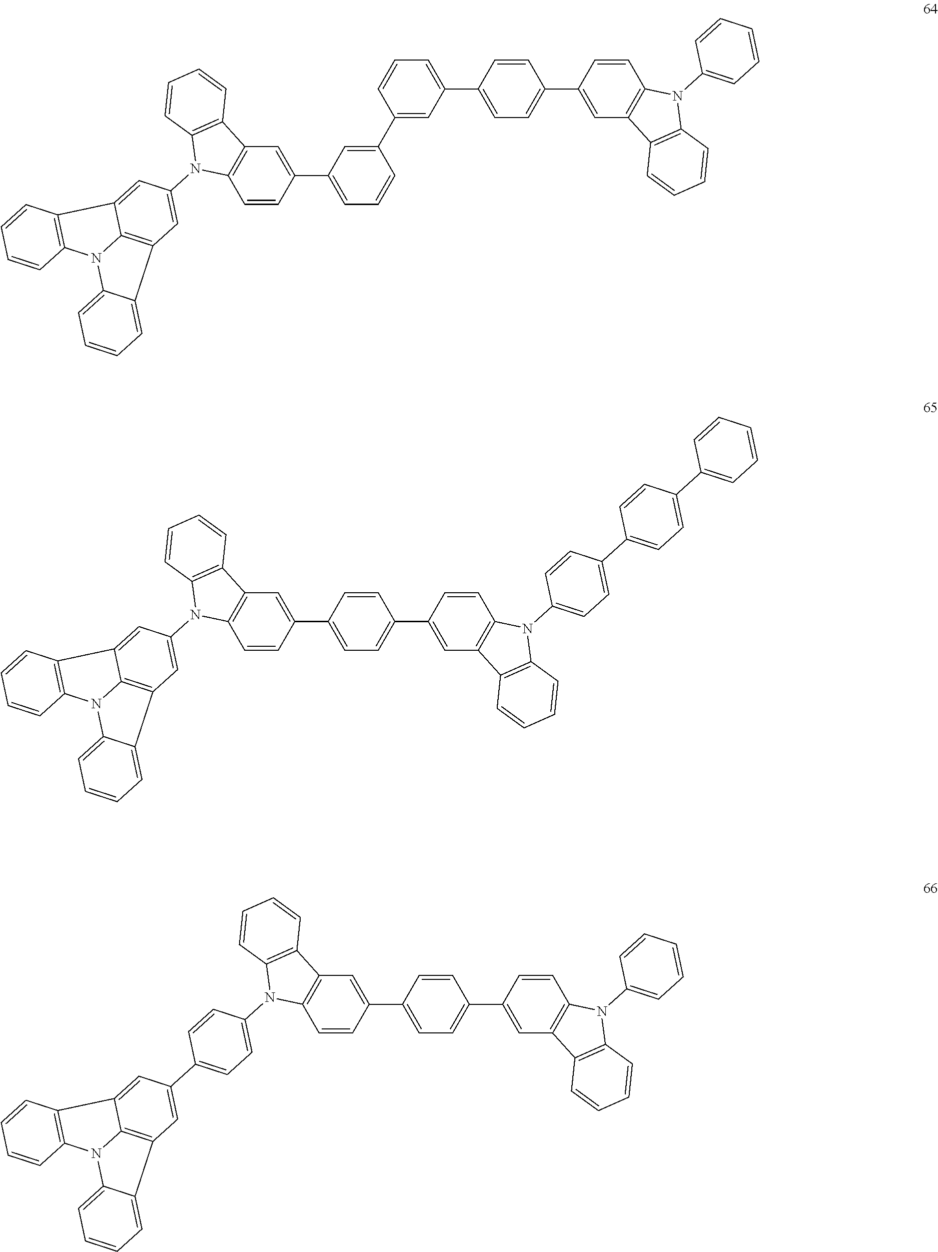 [SMILES: c1ccc(-n2c3ccccc3c3cc(-c4ccc(-c5cccc(-c6cccc(-c7ccc8c(c7)c7ccccc7n8-c7cc8c9ccccc9n9c%10ccccc%10c(c7)c89)c6)c5)cc4)ccc32)cc1 ; c1ccc(-c2ccc(-c3ccc(-n4c5ccccc5c5cc(-c6ccc(-c7ccc8c(c7)c7ccccc7n8-c7cc8c9ccccc9n9c%10ccccc%10c(c7)c89)cc6)ccc54)cc3)cc2)cc1 ; c1ccc(-n2c3ccccc3c3cc(-c4ccc(-c5ccc6c(c5)c5ccccc5n6-c5ccc(-c6cc7c8ccccc8n8c9ccccc9c(c6)c78)cc5)cc4)ccc32)cc1]

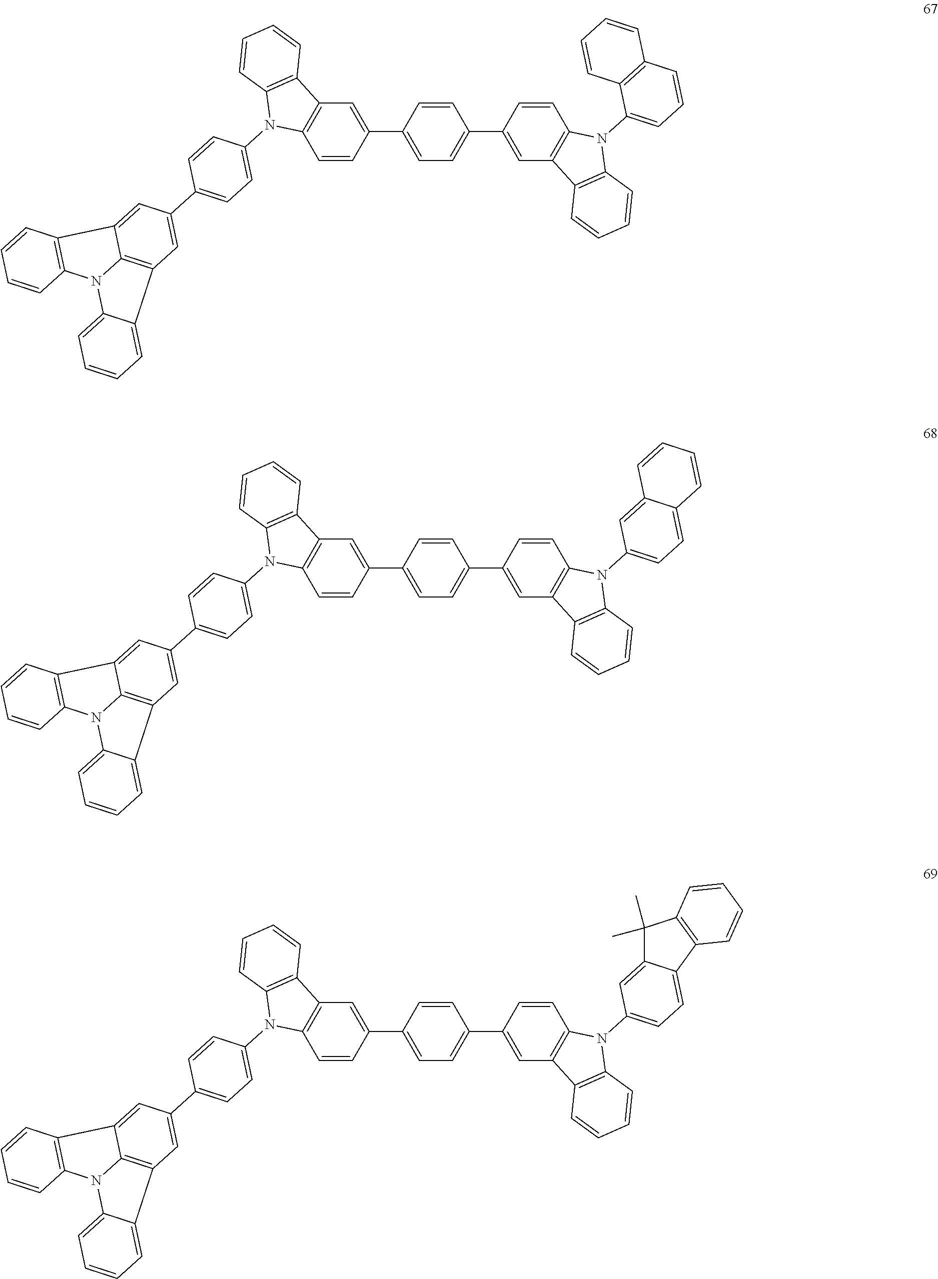 [SMILES: c1ccc2c(-n3c4ccccc4c4cc(-c5ccc(-c6ccc7c(c6)c6ccccc6n7-c6ccc(-c7cc8c9ccccc9n9c%10ccccc%10c(c7)c89)cc6)cc5)ccc43)cccc2c1 ; c1ccc2cc(-n3c4ccccc4c4cc(-c5ccc(-c6ccc7c(c6)c6ccccc6n7-c6ccc(-c7cc8c9ccccc9n9c%10ccccc%10c(c7)c89)cc6)cc5)ccc43)ccc2c1 ; CC1(C)c2ccccc2-c2ccc(-n3c4ccccc4c4cc(-c5ccc(-c6ccc7c(c6)c6ccccc6n7-c6ccc(-c7cc8c9ccccc9n9c%10ccccc%10c(c7)c89)cc6)cc5)ccc43)cc21]

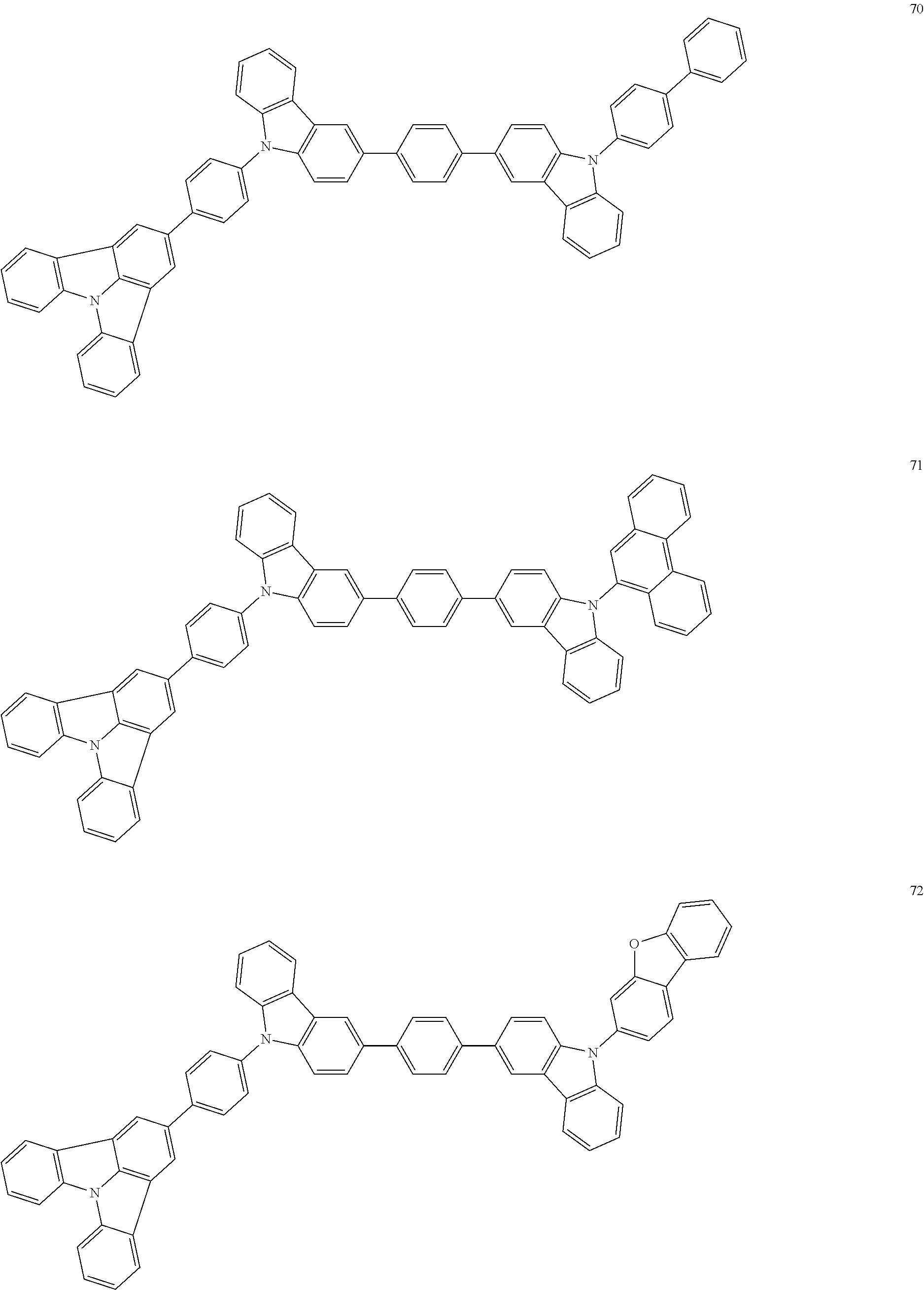 [SMILES: c1ccc(-c2ccc(-n3c4ccccc4c4cc(-c5ccc(-c6ccc7c(c6)c6ccccc6n7-c6ccc(-c7cc8c9ccccc9n9c%10ccccc%10c(c7)c89)cc6)cc5)ccc43)cc2)cc1 ; c1ccc2c(c1)cc(-n1c3ccccc3c3cc(-c4ccc(-c5ccc6c(c5)c5ccccc5n6-c5ccc(-c6cc7c8ccccc8n8c9ccccc9c(c6)c78)cc5)cc4)ccc31)c1ccccc12 ; c1ccc2c(c1)oc1cc(-n3c4ccccc4c4cc(-c5ccc(-c6ccc7c(c6)c6ccccc6n7-c6ccc(-c7cc8c9ccccc9n9c%10ccccc%10c(c7)c89)cc6)cc5)ccc43)ccc12]

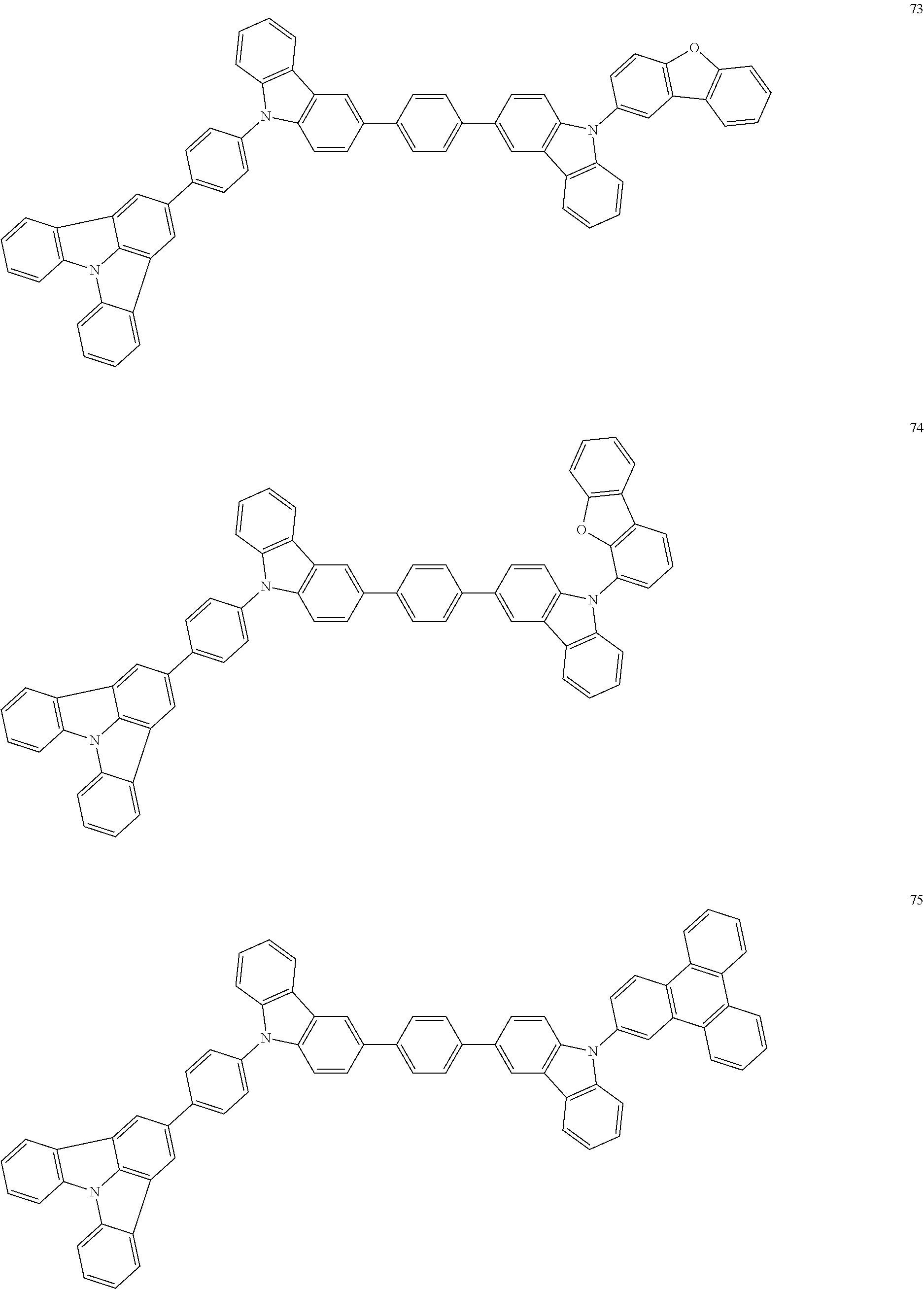 [SMILES: c1ccc2c(c1)oc1ccc(-n3c4ccccc4c4cc(-c5ccc(-c6ccc7c(c6)c6ccccc6n7-c6ccc(-c7cc8c9ccccc9n9c%10ccccc%10c(c7)c89)cc6)cc5)ccc43)cc12 ; c1ccc2c(c1)oc1c(-n3c4ccccc4c4cc(-c5ccc(-c6ccc7c(c6)c6ccccc6n7-c6ccc(-c7cc8c9ccccc9n9c%10ccccc%10c(c7)c89)cc6)cc5)ccc43)cccc12 ; c1ccc2c(c1)c1ccccc1c1cc(-n3c4ccccc4c4cc(-c5ccc(-c6ccc7c(c6)c6ccccc6n7-c6ccc(-c7cc8c9ccccc9n9c%10ccccc%10c(c7)c89)cc6)cc5)ccc43)ccc21]

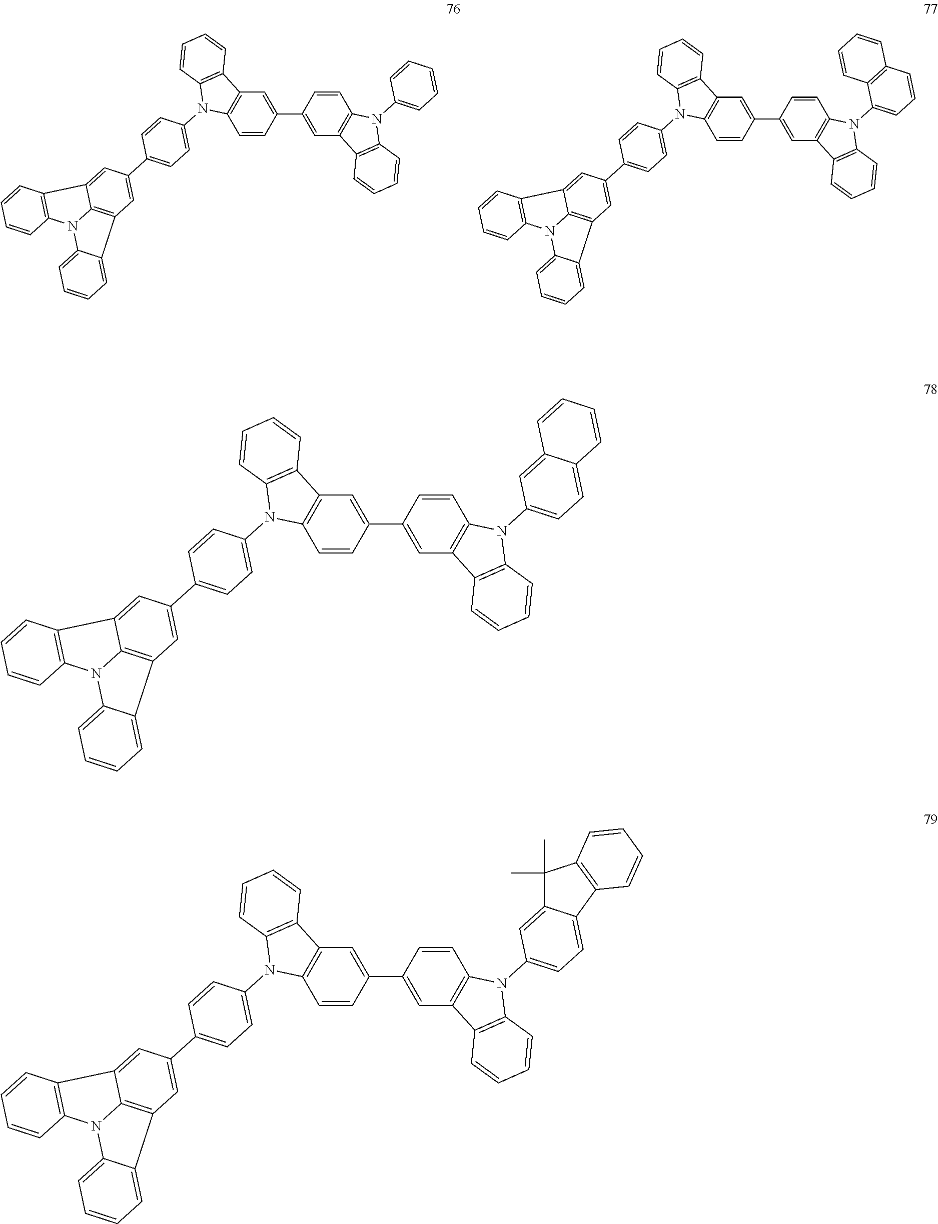 [SMILES: c1ccc(-n2c3ccccc3c3cc(-c4ccc5c(c4)c4ccccc4n5-c4ccc(-c5cc6c7ccccc7n7c8ccccc8c(c5)c67)cc4)ccc32)cc1 ; c1ccc2c(-n3c4ccccc4c4cc(-c5ccc6c(c5)c5ccccc5n6-c5ccc(-c6cc7c8ccccc8n8c9ccccc9c(c6)c78)cc5)ccc43)cccc2c1 ; c1ccc2cc(-n3c4ccccc4c4cc(-c5ccc6c(c5)c5ccccc5n6-c5ccc(-c6cc7c8ccccc8n8c9ccccc9c(c6)c78)cc5)ccc43)ccc2c1 ; CC1(C)c2ccccc2-c2ccc(-n3c4ccccc4c4cc(-c5ccc6c(c5)c5ccccc5n6-c5ccc(-c6cc7c8ccccc8n8c9ccccc9c(c6)c78)cc5)ccc43)cc21]

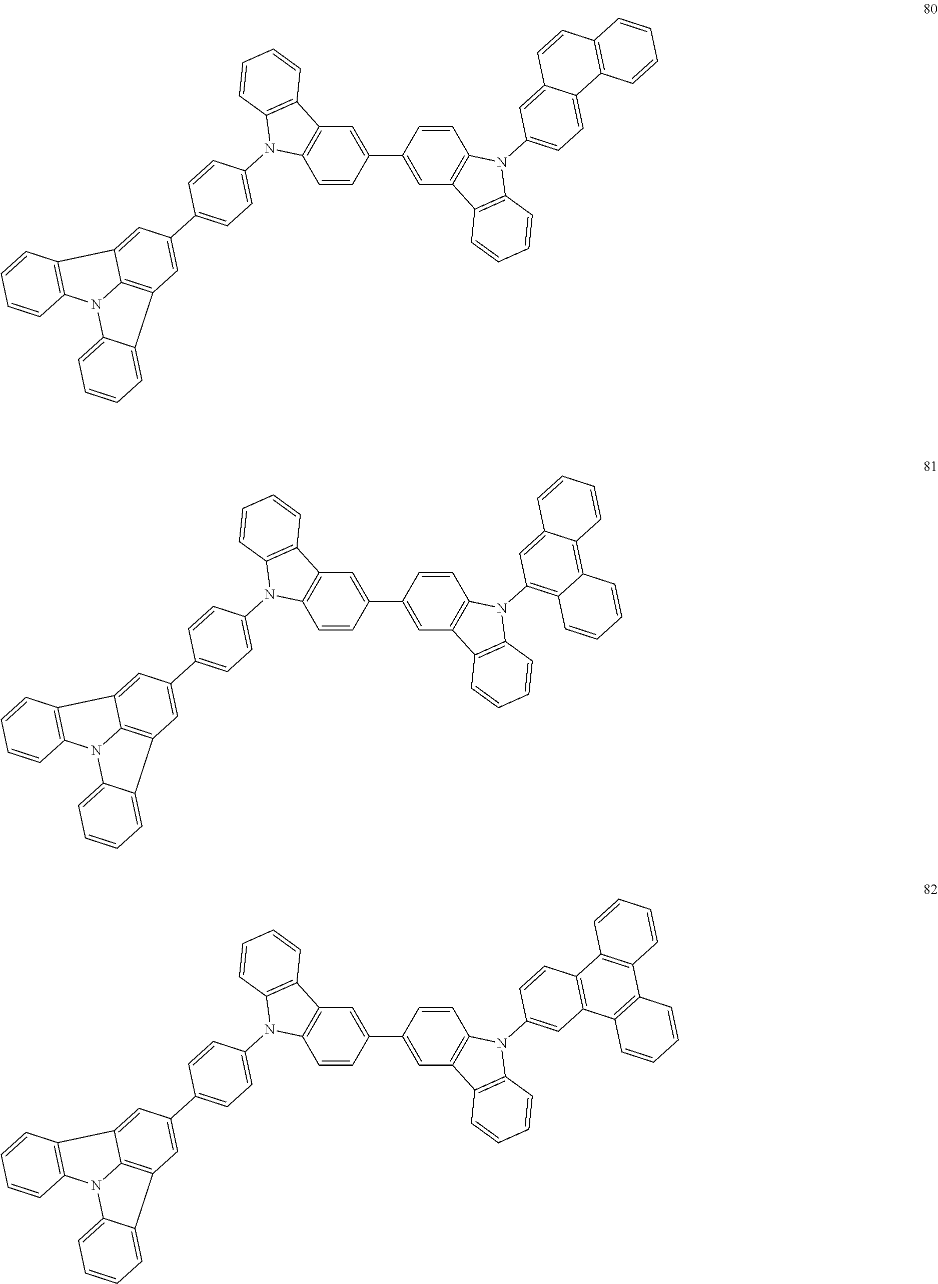 [SMILES: c1ccc2c(c1)ccc1cc(-n3c4ccccc4c4cc(-c5ccc6c(c5)c5ccccc5n6-c5ccc(-c6cc7c8ccccc8n8c9ccccc9c(c6)c78)cc5)ccc43)ccc12 ; c1ccc2c(c1)cc(-n1c3ccccc3c3cc(-c4ccc5c(c4)c4ccccc4n5-c4ccc(-c5cc6c7ccccc7n7c8ccccc8c(c5)c67)cc4)ccc31)c1ccccc12 ; c1ccc2c(c1)c1ccccc1c1cc(-n3c4ccccc4c4cc(-c5ccc6c(c5)c5ccccc5n6-c5ccc(-c6cc7c8ccccc8n8c9ccccc9c(c6)c78)cc5)ccc43)ccc21]

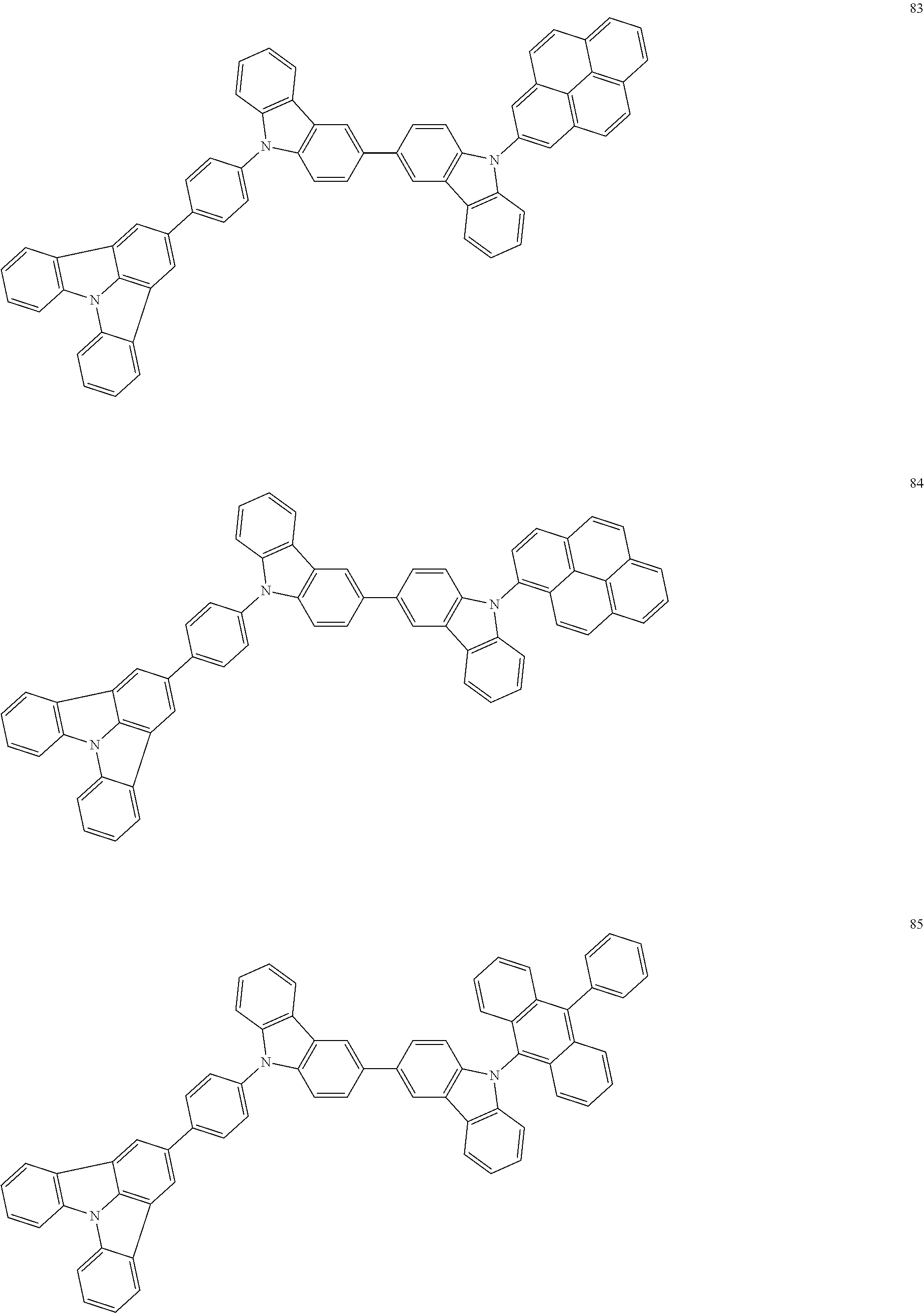 [SMILES: c1cc2ccc3cc(-n4c5ccccc5c5cc(-c6ccc7c(c6)c6ccccc6n7-c6ccc(-c7cc8c9ccccc9n9c%10ccccc%10c(c7)c89)cc6)ccc54)cc4ccc(c1)c2c34 ; c1cc2ccc3ccc(-n4c5ccccc5c5cc(-c6ccc7c(c6)c6ccccc6n7-c6ccc(-c7cc8c9ccccc9n9c%10ccccc%10c(c7)c89)cc6)ccc54)c4ccc(c1)c2c34 ; c1ccc(-c2c3ccccc3c(-n3c4ccccc4c4cc(-c5ccc6c(c5)c5ccccc5n6-c5ccc(-c6cc7c8ccccc8n8c9ccccc9c(c6)c78)cc5)ccc43)c3ccccc23)cc1]

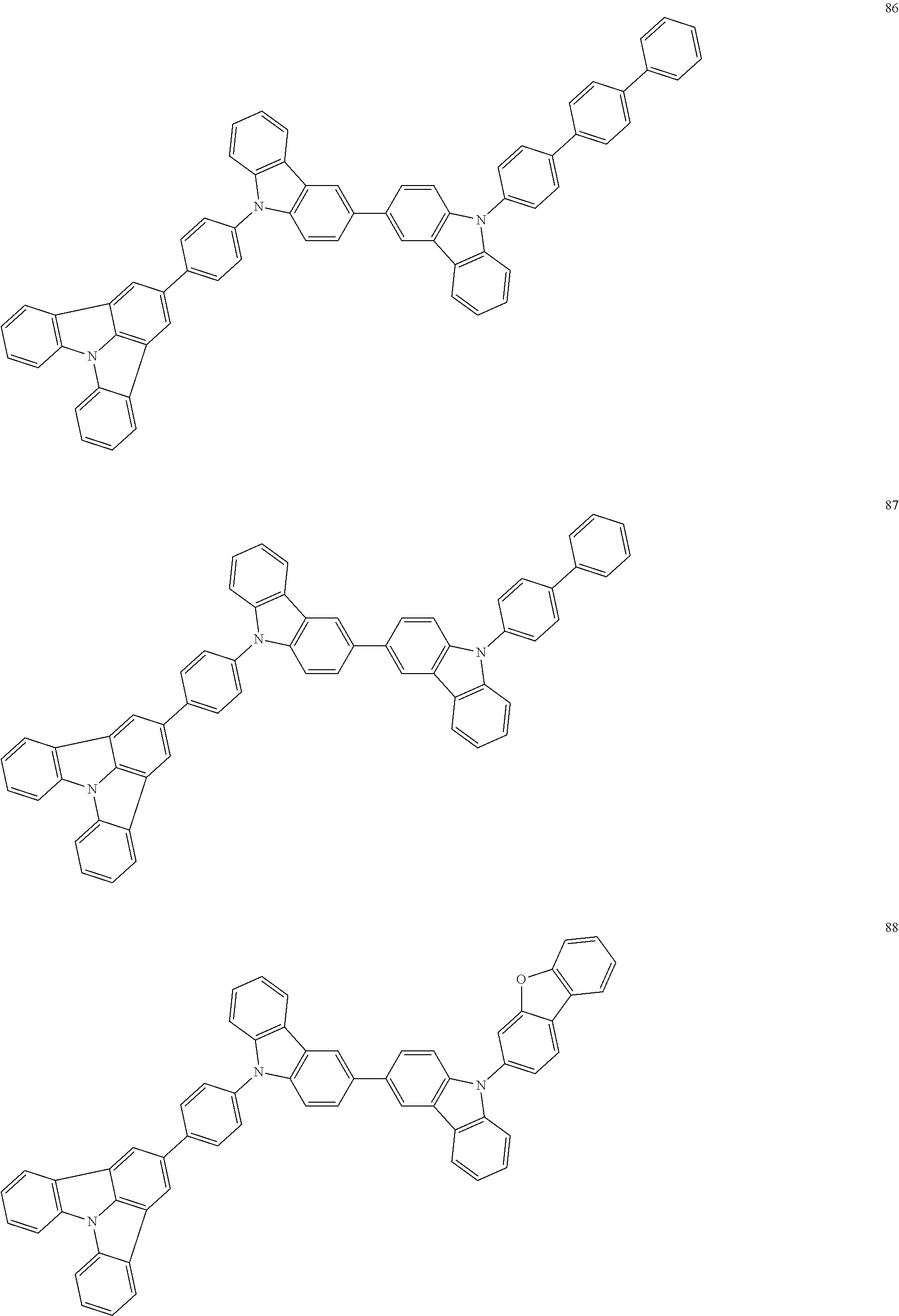 [SMILES: c1ccc(-c2ccc(-c3ccc(-n4c5ccccc5c5cc(-c6ccc7c(c6)c6ccccc6n7-c6ccc(-c7cc8c9ccccc9n9c%10ccccc%10c(c7)c89)cc6)ccc54)cc3)cc2)cc1 ; c1ccc(-c2ccc(-n3c4ccccc4c4cc(-c5ccc6c(c5)c5ccccc5n6-c5ccc(-c6cc7c8ccccc8n8c9ccccc9c(c6)c78)cc5)ccc43)cc2)cc1 ; c1ccc2c(c1)oc1cc(-n3c4ccccc4c4cc(-c5ccc6c(c5)c5ccccc5n6-c5ccc(-c6cc7c8ccccc8n8c9ccccc9c(c6)c78)cc5)ccc43)ccc12]

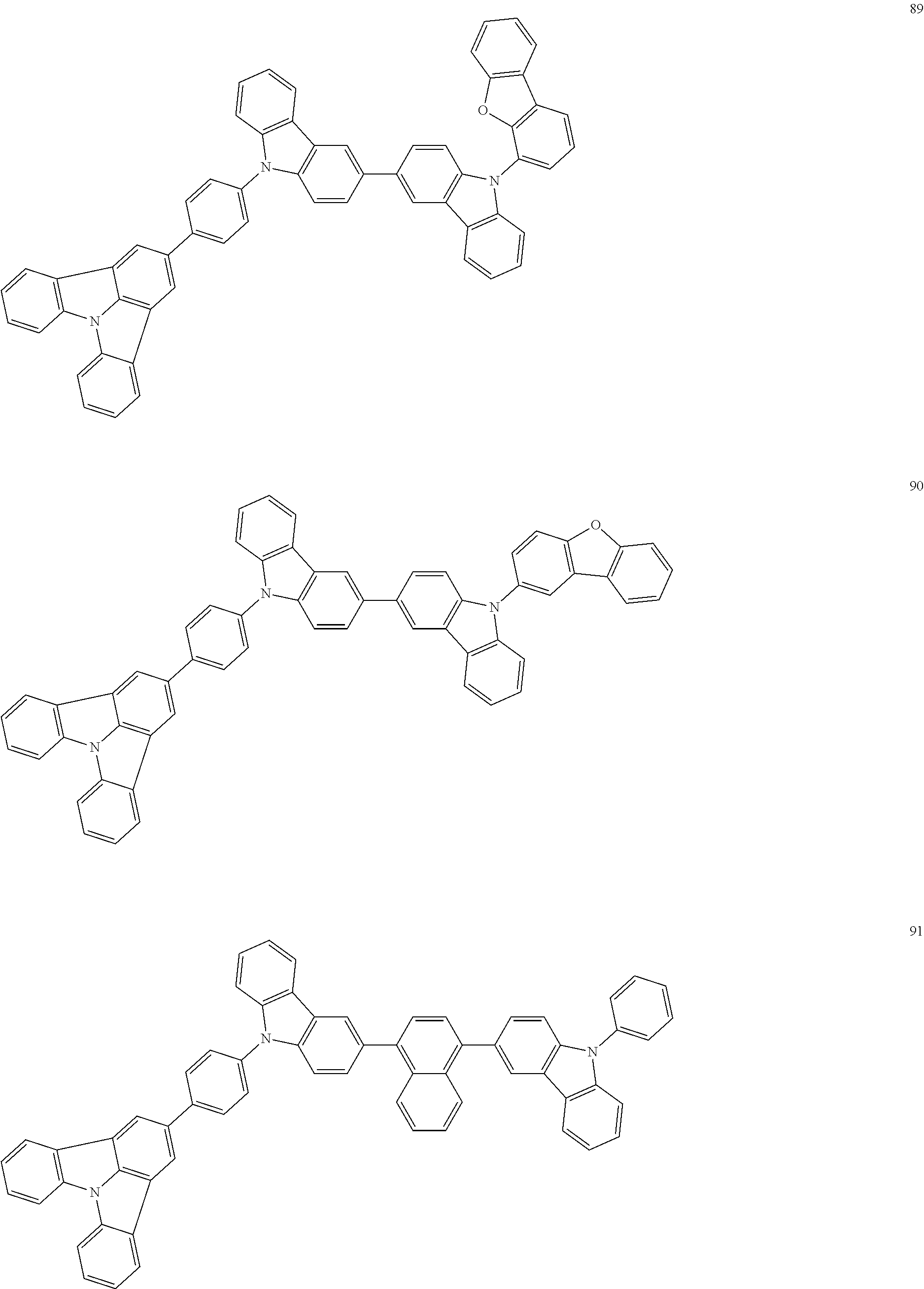 [SMILES: c1ccc2c(c1)oc1c(-n3c4ccccc4c4cc(-c5ccc6c(c5)c5ccccc5n6-c5ccc(-c6cc7c8ccccc8n8c9ccccc9c(c6)c78)cc5)ccc43)cccc12 ; c1ccc2c(c1)oc1ccc(-n3c4ccccc4c4cc(-c5ccc6c(c5)c5ccccc5n6-c5ccc(-c6cc7c8ccccc8n8c9ccccc9c(c6)c78)cc5)ccc43)cc12 ; c1ccc(-n2c3ccccc3c3cc(-c4ccc(-c5ccc6c(c5)c5ccccc5n6-c5ccc(-c6cc7c8ccccc8n8c9ccccc9c(c6)c78)cc5)c5ccccc45)ccc32)cc1]

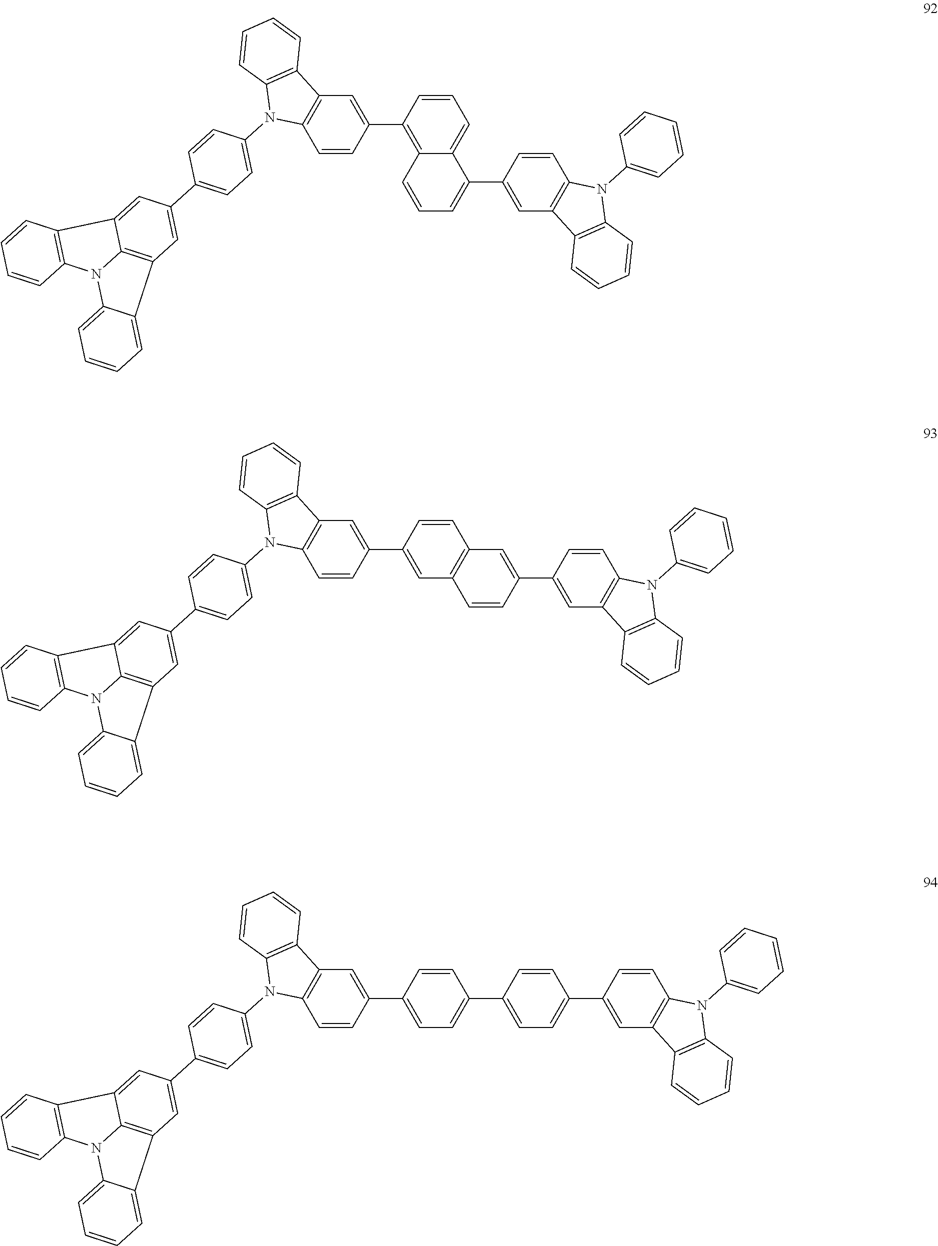 [SMILES: c1ccc(-n2c3ccccc3c3cc(-c4cccc5c(-c6ccc7c(c6)c6ccccc6n7-c6ccc(-c7cc8c9ccccc9n9c%10ccccc%10c(c7)c89)cc6)cccc45)ccc32)cc1 ; c1ccc(-n2c3ccccc3c3cc(-c4ccc5cc(-c6ccc7c(c6)c6ccccc6n7-c6ccc(-c7cc8c9ccccc9n9c%10ccccc%10c(c7)c89)cc6)ccc5c4)ccc32)cc1 ; c1ccc(-n2c3ccccc3c3cc(-c4ccc(-c5ccc(-c6ccc7c(c6)c6ccccc6n7-c6ccc(-c7cc8c9ccccc9n9c%10ccccc%10c(c7)c89)cc6)cc5)cc4)ccc32)cc1]

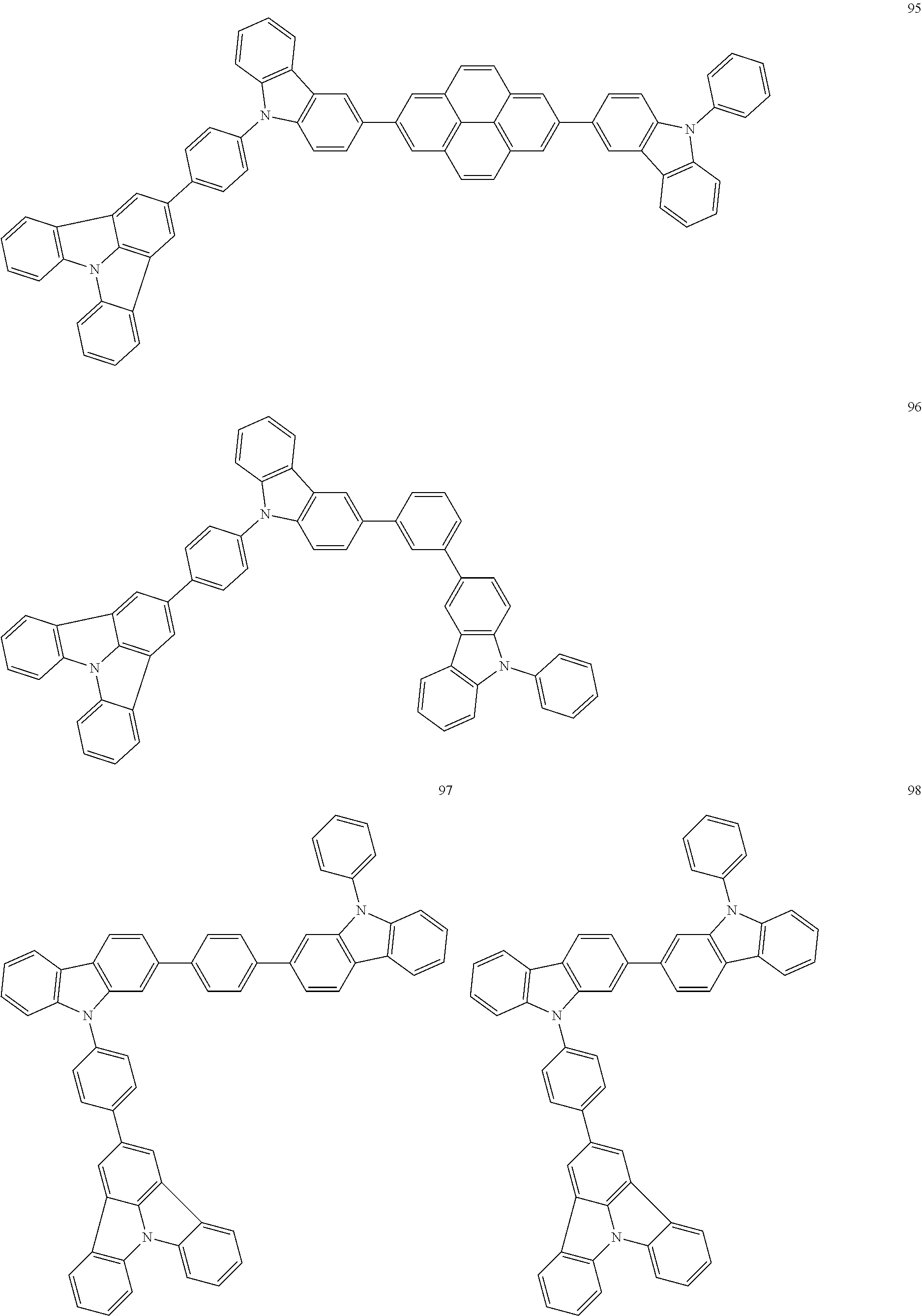

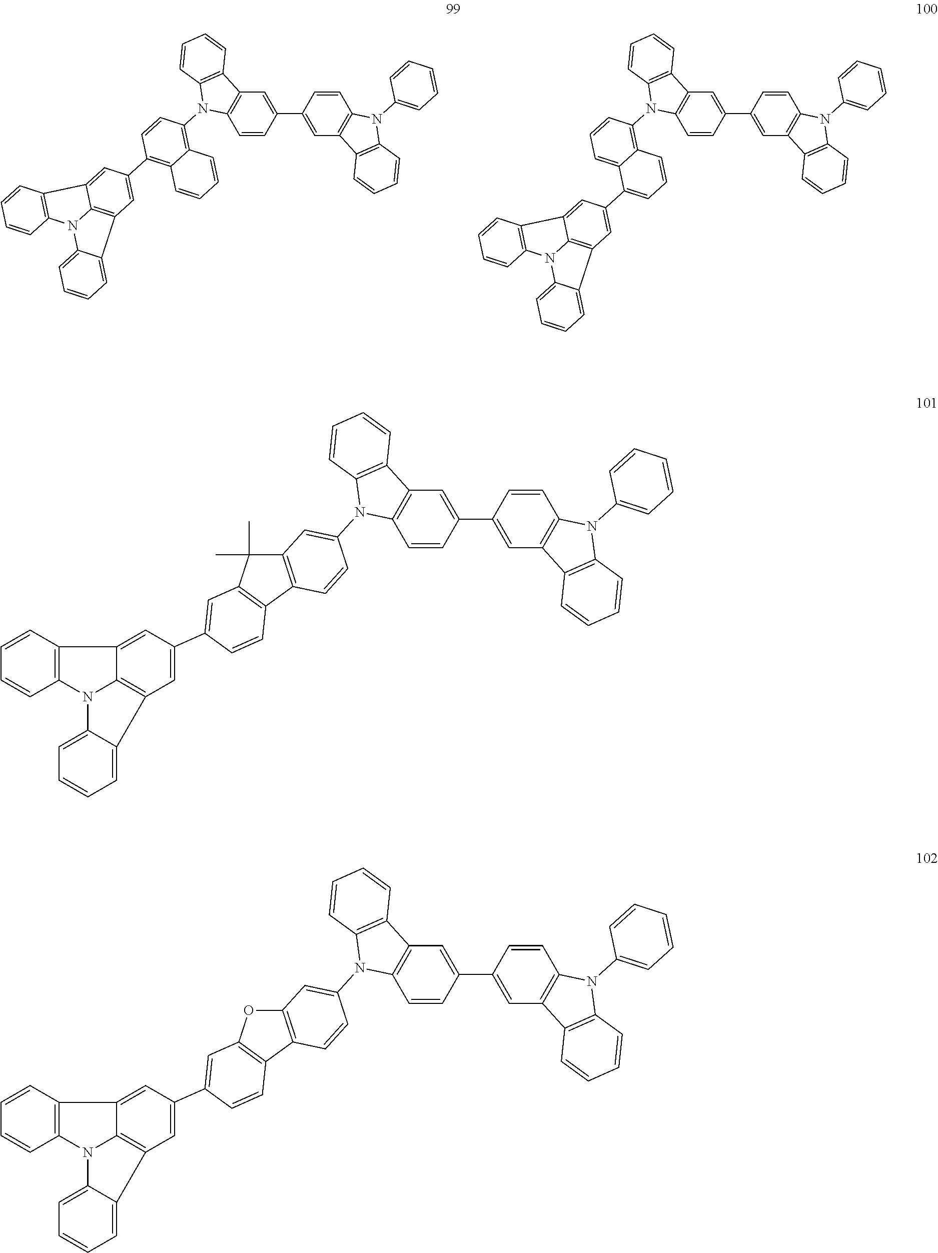 [SMILES: c1ccc(-n2c3ccccc3c3cc(-c4ccc5c(c4)c4ccccc4n5-c4ccc(-c5cc6c7ccccc7n7c8ccccc8c(c5)c67)c5ccccc45)ccc32)cc1 ; c1ccc(-n2c3ccccc3c3cc(-c4ccc5c(c4)c4ccccc4n5-c4cccc5c(-c6cc7c8ccccc8n8c9ccccc9c(c6)c78)cccc45)ccc32)cc1 ; CC1(C)c2cc(-c3cc4c5ccccc5n5c6ccccc6c(c3)c45)ccc2-c2ccc(-n3c4ccccc4c4cc(-c5ccc6c(c5)c5ccccc5n6-c5ccccc5)ccc43)cc21 ; c1ccc(-n2c3ccccc3c3cc(-c4ccc5c(c4)c4ccccc4n5-c4ccc5c(c4)oc4cc(-c6cc7c8ccccc8n8c9ccccc9c(c6)c78)ccc45)ccc32)cc1]

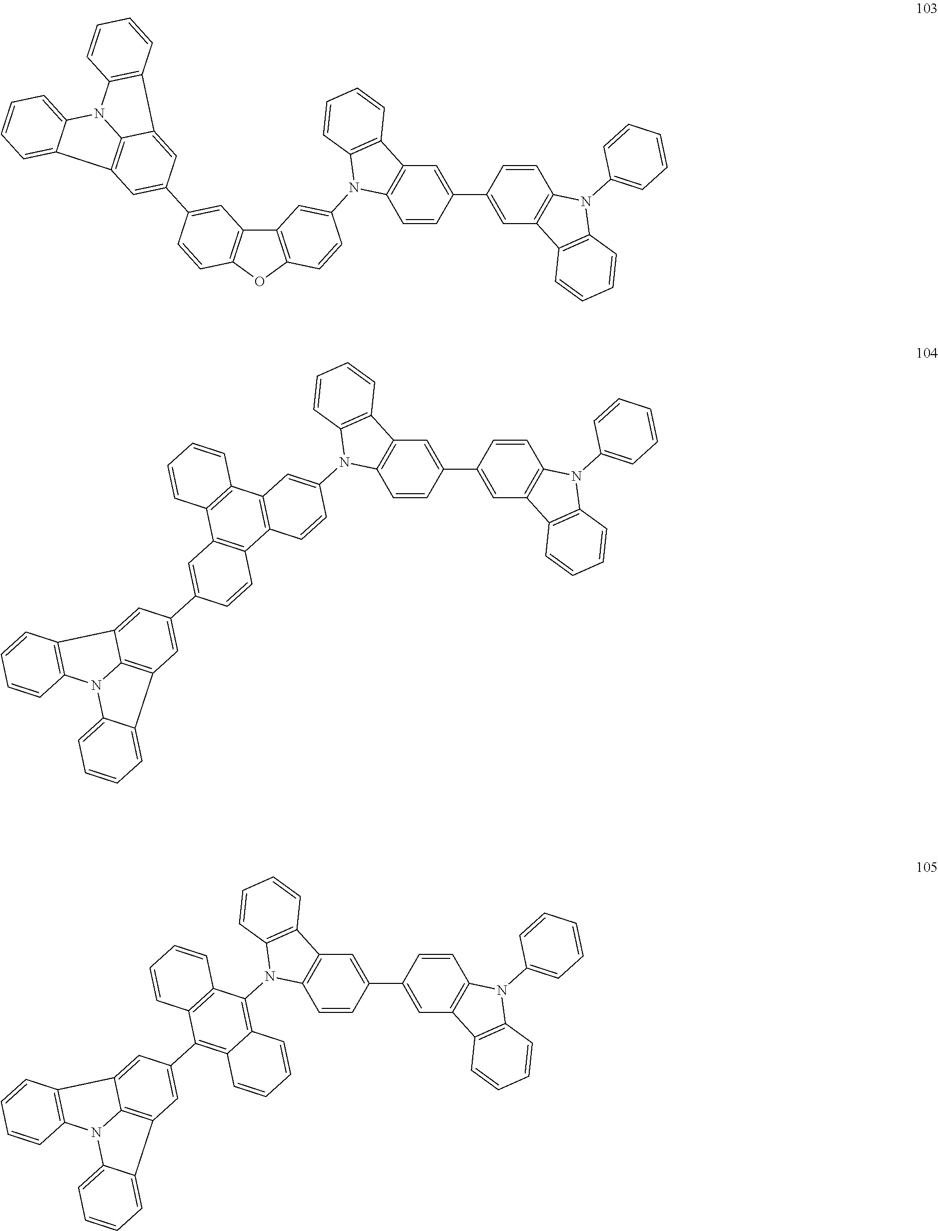 [SMILES: c1ccc(-n2c3ccccc3c3cc(-c4ccc5c(c4)c4ccccc4n5-c4ccc5oc6ccc(-c7cc8c9ccccc9n9c%10ccccc%10c(c7)c89)cc6c5c4)ccc32)cc1 ; c1ccc(-n2c3ccccc3c3cc(-c4ccc5c(c4)c4ccccc4n5-c4ccc5c6ccc(-c7cc8c9ccccc9n9c%10ccccc%10c(c7)c89)cc6c6ccccc6c5c4)ccc32)cc1 ; c1ccc(-n2c3ccccc3c3cc(-c4ccc5c(c4)c4ccccc4n5-c4c5ccccc5c(-c5cc6c7ccccc7n7c8ccccc8c(c5)c67)c5ccccc45)ccc32)cc1]

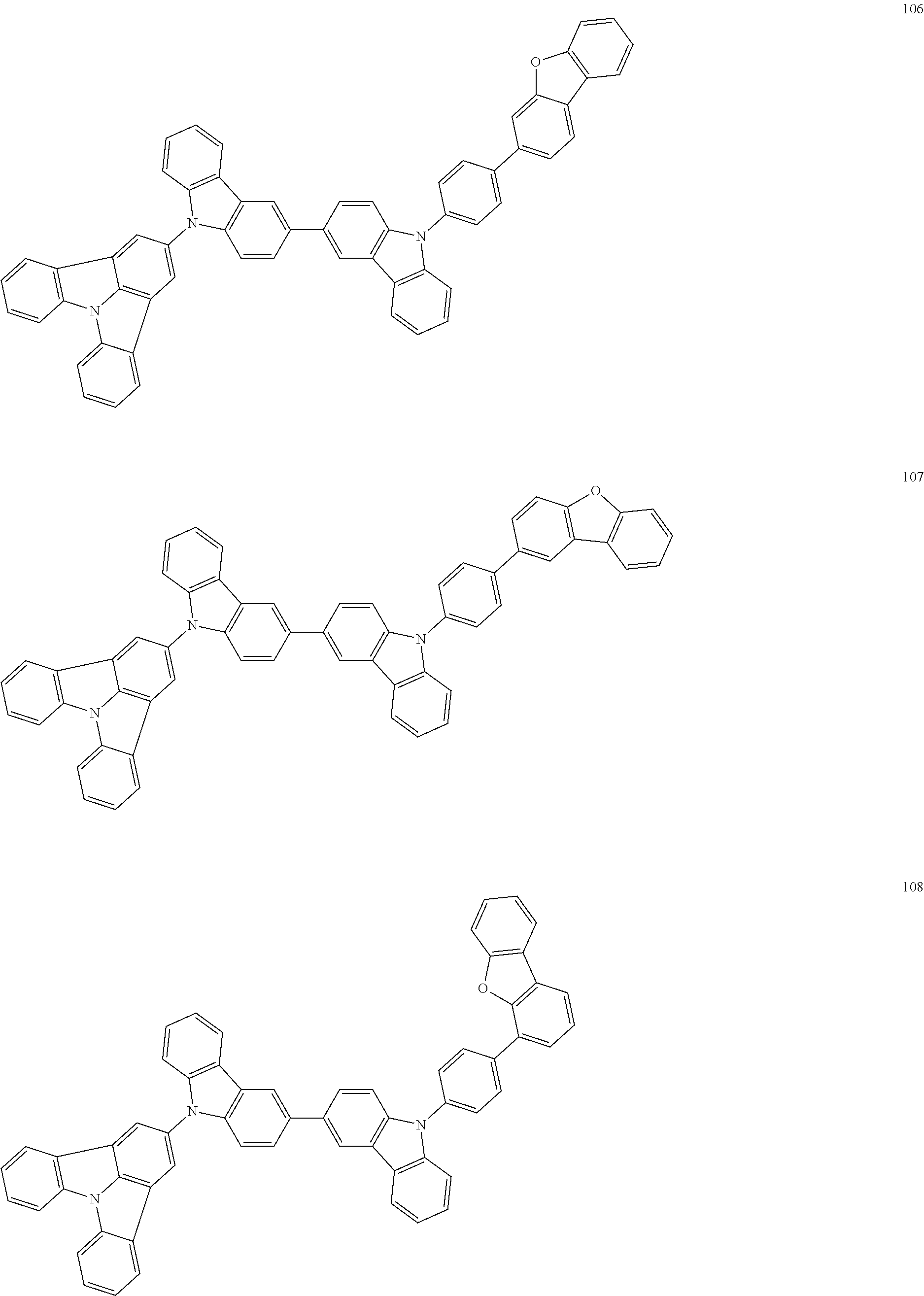 [SMILES: c1ccc2c(c1)oc1cc(-c3ccc(-n4c5ccccc5c5cc(-c6ccc7c(c6)c6ccccc6n7-c6cc7c8ccccc8n8c9ccccc9c(c6)c78)ccc54)cc3)ccc12 ; c1ccc2c(c1)oc1ccc(-c3ccc(-n4c5ccccc5c5cc(-c6ccc7c(c6)c6ccccc6n7-c6cc7c8ccccc8n8c9ccccc9c(c6)c78)ccc54)cc3)cc12 ; c1ccc2c(c1)oc1c(-c3ccc(-n4c5ccccc5c5cc(-c6ccc7c(c6)c6ccccc6n7-c6cc7c8ccccc8n8c9ccccc9c(c6)c78)ccc54)cc3)cccc12]

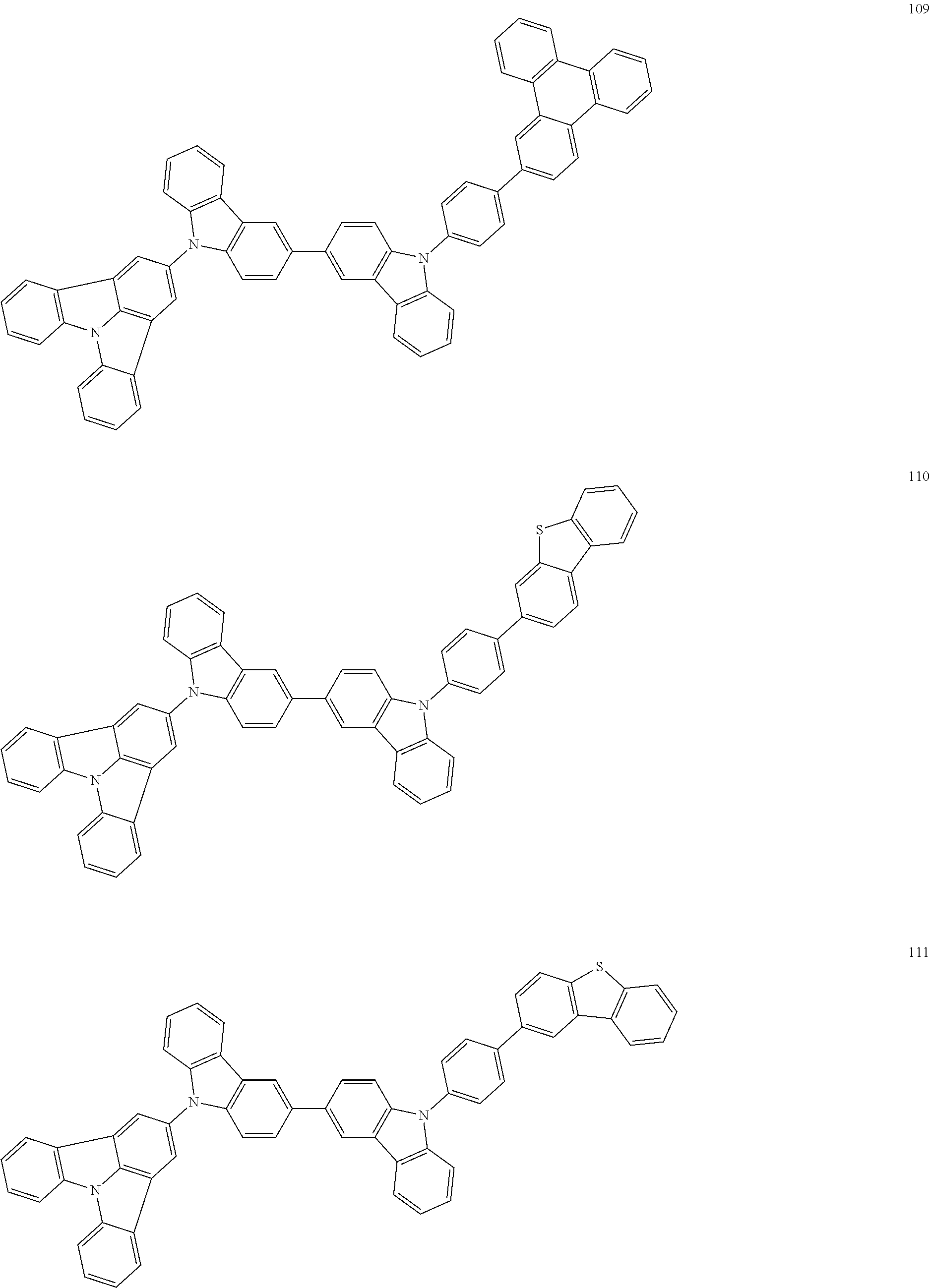 [SMILES: c1ccc2c(c1)c1ccccc1c1cc(-c3ccc(-n4c5ccccc5c5cc(-c6ccc7c(c6)c6ccccc6n7-c6cc7c8ccccc8n8c9ccccc9c(c6)c78)ccc54)cc3)ccc21 ; c1ccc2c(c1)sc1cc(-c3ccc(-n4c5ccccc5c5cc(-c6ccc7c(c6)c6ccccc6n7-c6cc7c8ccccc8n8c9ccccc9c(c6)c78)ccc54)cc3)ccc12 ; c1ccc2c(c1)sc1ccc(-c3ccc(-n4c5ccccc5c5cc(-c6ccc7c(c6)c6ccccc6n7-c6cc7c8ccccc8n8c9ccccc9c(c6)c78)ccc54)cc3)cc12]

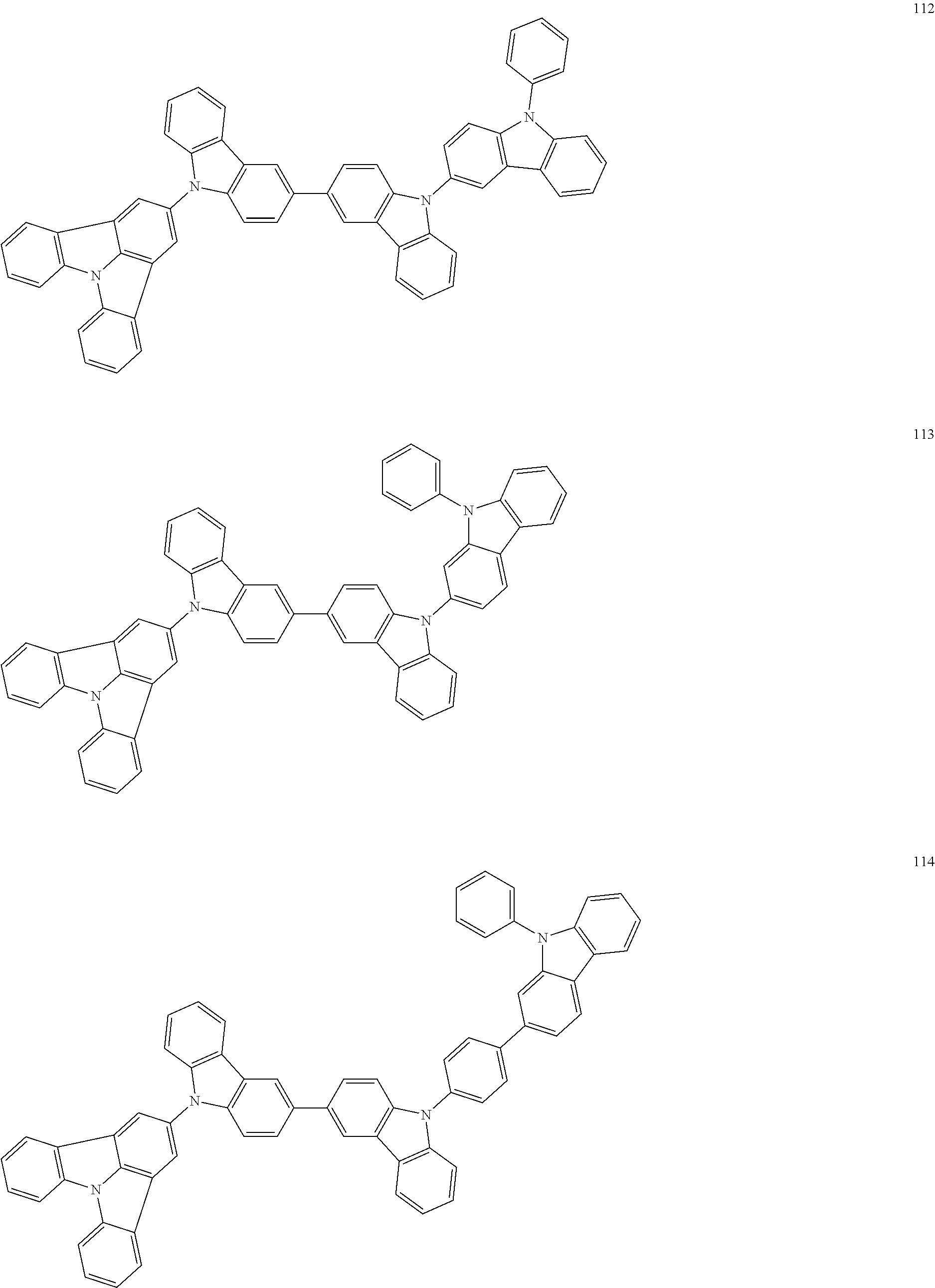 [SMILES: c1ccc(-n2c3ccccc3c3cc(-n4c5ccccc5c5cc(-c6ccc7c(c6)c6ccccc6n7-c6cc7c8ccccc8n8c9ccccc9c(c6)c78)ccc54)ccc32)cc1 ; c1ccc(-n2c3ccccc3c3ccc(-n4c5ccccc5c5cc(-c6ccc7c(c6)c6ccccc6n7-c6cc7c8ccccc8n8c9ccccc9c(c6)c78)ccc54)cc32)cc1 ; c1ccc(-n2c3ccccc3c3ccc(-c4ccc(-n5c6ccccc6c6cc(-c7ccc8c(c7)c7ccccc7n8-c7cc8c9ccccc9n9c%10ccccc%10c(c7)c89)ccc65)cc4)cc32)cc1]

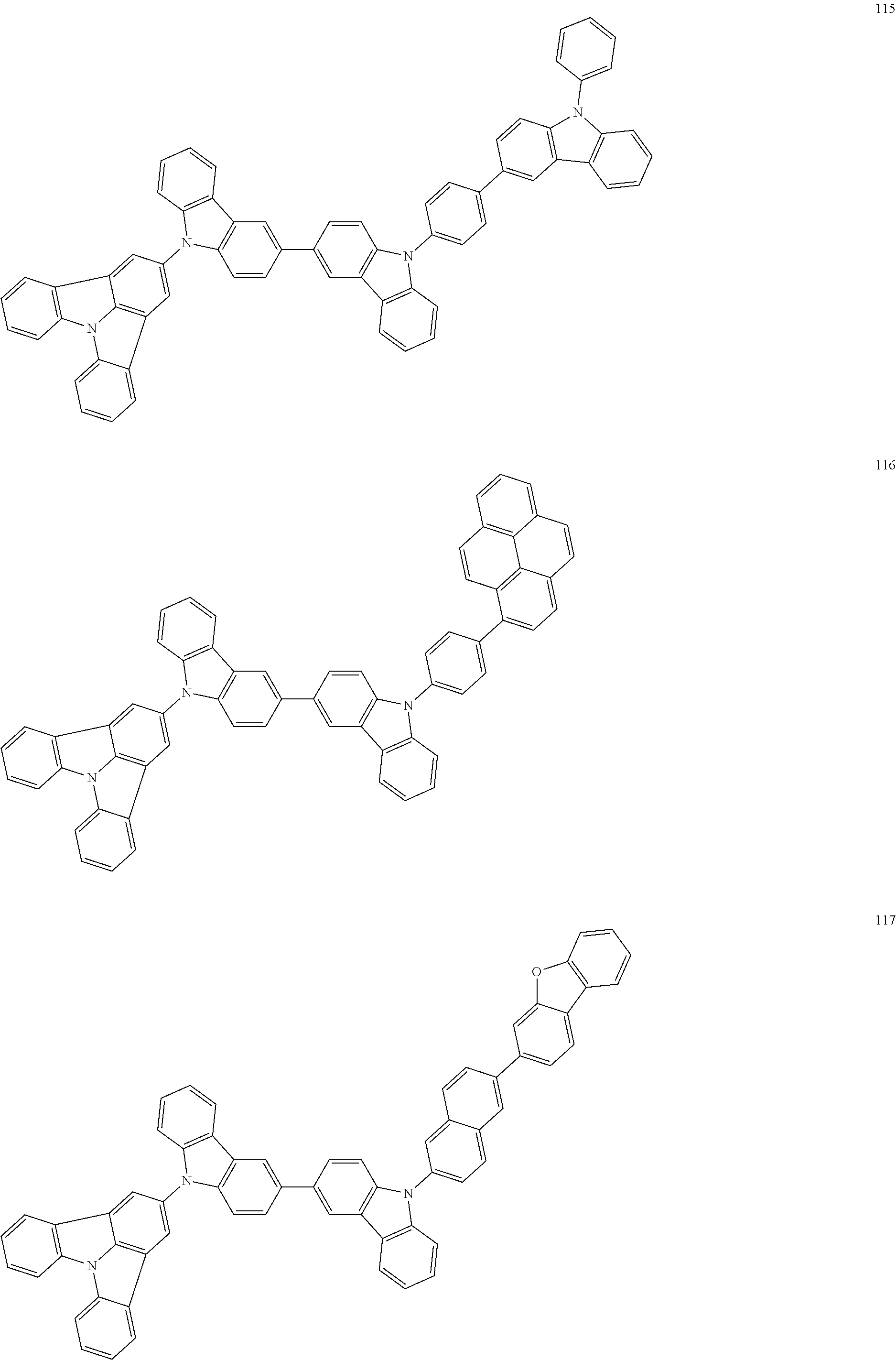 [SMILES: c1ccc(-n2c3ccccc3c3cc(-c4ccc(-n5c6ccccc6c6cc(-c7ccc8c(c7)c7ccccc7n8-c7cc8c9ccccc9n9c%10ccccc%10c(c7)c89)ccc65)cc4)ccc32)cc1 ; c1cc2ccc3ccc(-c4ccc(-n5c6ccccc6c6cc(-c7ccc8c(c7)c7ccccc7n8-c7cc8c9ccccc9n9c%10ccccc%10c(c7)c89)ccc65)cc4)c4ccc(c1)c2c34 ; c1ccc2c(c1)oc1cc(-c3ccc4cc(-n5c6ccccc6c6cc(-c7ccc8c(c7)c7ccccc7n8-c7cc8c9ccccc9n9c%10ccccc%10c(c7)c89)ccc65)ccc4c3)ccc12]

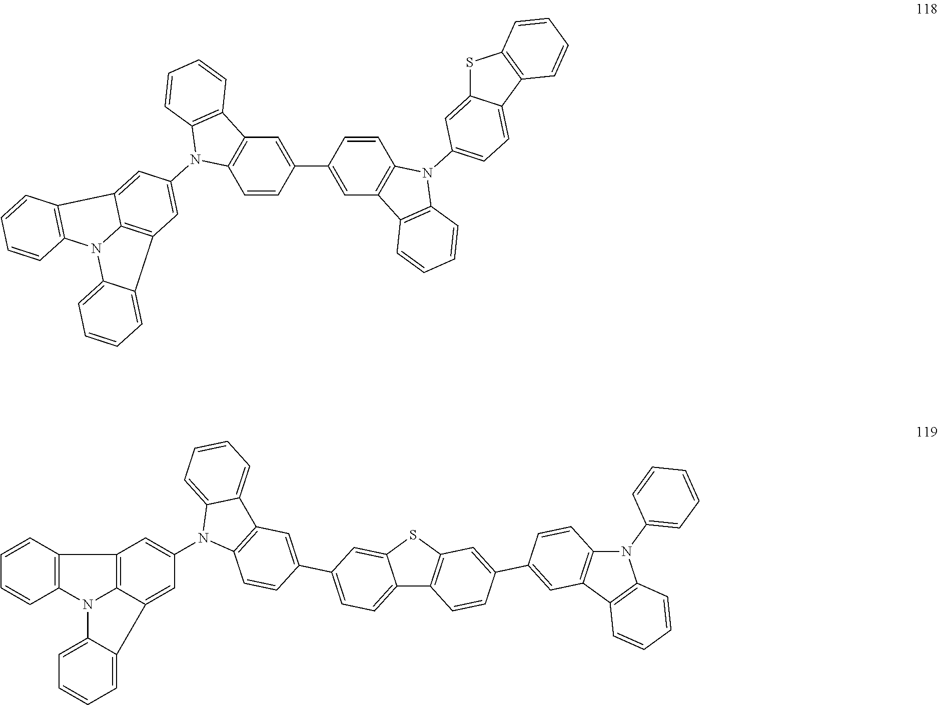 [SMILES: c1ccc2c(c1)sc1cc(-n3c4ccccc4c4cc(-c5ccc6c(c5)c5ccccc5n6-c5cc6c7ccccc7n7c8ccccc8c(c5)c67)ccc43)ccc12 ; c1ccc(-n2c3ccccc3c3cc(-c4ccc5c(c4)sc4cc(-c6ccc7c(c6)c6ccccc6n7-c6cc7c8ccccc8n8c9ccccc9c(c6)c78)ccc45)ccc32)cc1]

In an implementation, the compound for an organic EL device according to an embodiment may be appropriately used or included in a layer (of stacking layers) between an emission layer and an anode (e.g., in an organic EL device). In an implementation, the compound for an organic EL device according to an embodiment may be used or included in the emission layer of an organic EL device. The material for an organic EL device according to an embodiment may be used in the layer of layers stacked between the emission layer and the anode or in the emission layer, and the electron tolerance of a layer including the material for an organic EL device according to an embodiment may be improved. Thus, an organic EL device having high efficiency and long life may be manufactured. In addition, the driving voltage thereof may be decreased. In addition, the compound for an organic EL device according to an embodiment may be suitably used in an emission layer or in a layer (of layers) between the emission layer and an anode of an organic EL device of a blue emission region.

(Organic EL Device)

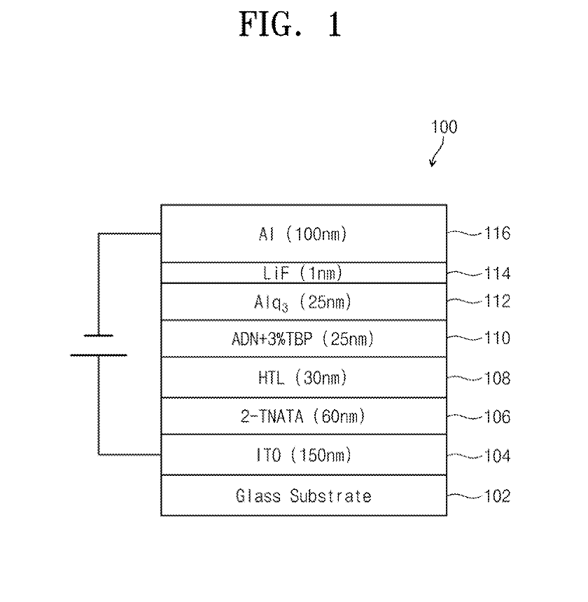

An organic EL device using or including the compound for an organic EL device according to an embodiment will be explained. FIG. 1 illustrates a diagram of the configuration of an organic EL device 100 according to an embodiment. The organic EL device 100 may include, e.g., a substrate 102, an anode 104, a hole injection layer 106, a hole transport layer 108, an emission layer 110, an electron transport layer 112, an electron injection layer 114, and a cathode 116. In an implementation, the compound for an organic EL device according to an embodiment may be included in one layer of layers stacked between the emission layer 110 and the anode 104. In an implementation, the compound may be included in the emission layer 110 of the organic EL device 100.

In an implementation, the compound for an organic EL device according to an embodiment may be included in the hole transport layer 108. The substrate 102 may be, e.g., a transparent glass substrate, a semiconductor substrate formed by using silicon, etc., or a flexible substrate of a resin, etc. The anode 104 may be disposed on the substrate 102 and may be formed by using, e.g., indium tin oxide (ITO), indium zinc oxide (IZO), etc. The hole injection layer 106 may be disposed on the anode 104 and may include, e.g., 4,4′,4″-tris(N-1-naphthyl-N-phenylamino)triphenylamine (1-TNATA), 4,4′,4″-tris(N-(2-naphthyl)-N-phenylamino)triphenylamine (2-TNATA), N,N,N′,N′-tetrakis(3-methylphenyl)-3,3′-dimethylbenzidine (HMTPD), etc. The hole transport layer 108 may be disposed on the hole injection layer 106 and may be formed by using the compound for an organic EL device according to an embodiment. The emission layer 110 may be disposed on the hole transport layer 108 and may be formed by using, e.g., a host material including 9,10-di(2-naphthyl)anthracene (ADN), etc. doped with 2,5,8,11-tetra-t-butylperylene (TBP). The electron transport layer 112 may be disposed on the emission layer 110 and may be formed by using, e.g., a material including tris(8-hydroxyquinolinato)aluminum (Alq₃). The electron injection layer 114 may be disposed on the electron transport layer 112 and may be formed by using, e.g., a material including lithium fluoride (LiF). The cathode 116 may be disposed on the electron injection layer 114 and may be formed by using a metal such as Al or a transparent material such as indium tin oxide (ITO), indium zinc oxide (IZO), etc. The above-described thin layers may be formed by selecting a suitable layer forming method such as vacuum deposition, sputtering, various coatings, etc.

In the organic EL device 100 according to an embodiment, a hole transport layer having high efficiency and long life may be formed by using the compound for an organic EL device described above. In an implementation, the compound for an organic EL device described above may be applied in an organic EL apparatus of an active matrix type using thin film transistors (TFT).

The organic EL device 100 may include the compound for an organic EL device in an emission layer or a layer (of layers) stacked between the emission layer and an anode, high efficiency and long life of the organic EL device may be realized.

(Preparation Method)

The above-described compounds for an organic EL device according to an embodiment may be synthesized, e.g., by the following methods. For example, each compound may be prepared by the first synthesis and the second synthesis with different amounts.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

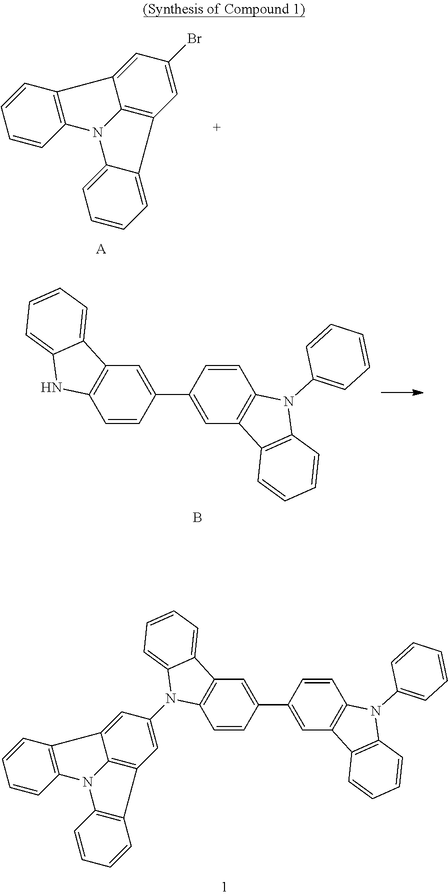

First Synthesis

An indolocarbazole compound A (5 mmol), a carbazole compound B (5 mmol), a palladium catalyst (0.5 mol), a phosphine ligand (2 mol), an alkaline reagent (20 mmol), and toluene (300 mL) were added in a reaction vessel, followed by substituting air in the vessel with nitrogen and stirring while refluxing for 15 minutes. After cooling by standing, water was added in the reactant, and extraction of an organic layer was performed. The obtained organic layer was dried with magnesium sulfate anhydrous and filtered, and the obtained filtrate was concentrated using a rotary evaporator. The obtained crude product was separated by silica gel column chromatography, and the obtained solid was recrystallized to produce a target product, Compound 1, as a solid powder with a yield of 30% (APCI+: C₄₈H₂₉N₃, measured value 647).

Second Synthesis

An indolocarbazole compound A (10 mmol), a carbazole compound B (10 mmol), a palladium catalyst (1 mol), a phosphine ligand (4 mol), a basic reagent (20 mmol), and toluene (500 mL) were added in a reaction vessel, followed by substituting air in the vessel with nitrogen and stirring while refluxing for 15 minutes. After cooling by standing, water was added in the reactant, and extraction of an organic layer was performed. The obtained organic layer was dried with magnesium sulfate anhydrous and filtered, and the obtained filtrate was concentrated using a rotary evaporator. The obtained crude product was separated by silica gel column chromatography, and the obtained solid was recrystallized to produce a target product, Compound 1, as a solid powder with a yield of 55% (APCI+: C₄₈H₂₉N₃, measured value 647).

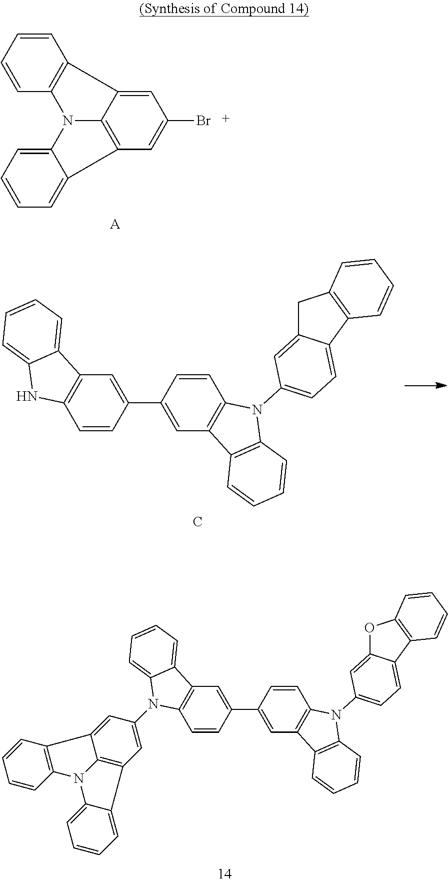

First Synthesis

An indolocarbazole compound A (7 mmol), a carbazole compound C (7 mmol), a palladium catalyst (0.7 mol), a phosphine ligand (2.8 mol), a basic reagent (28 mmol), and toluene (400 mL) were added in a reaction vessel, followed by substituting air in the vessel with nitrogen and stirring while refluxing for 12 hours. After cooling by standing, water was added in the reactant, and extraction of an organic layer was performed. The obtained organic layer was dried with magnesium sulfate anhydrous and filtered, and the obtained filtrate was concentrated using a rotary evaporator. The obtained crude product was separated by silica gel column chromatography, and the obtained solid was recrystallized to produce a target product, Compound 14, as a solid powder with a yield of 25% (APCI+: C₅₄H₃₁N₃O, measured value 737).

Second Synthesis

An indolocarbazole compound A (9 mmol), a carbazole compound C (9 mmol), a palladium catalyst (0.9 mol), a phosphine ligand (3.6 mol), a basic reagent (36 mmol), and toluene (500 mL) were added in a reaction vessel, followed by substituting air in the vessel with nitrogen and stirring while refluxing for 12 hours. After cooling by standing, water was added in the reactant, and extraction of an organic layer was performed. The obtained organic layer was dried with magnesium sulfate anhydrous and filtered, and the obtained filtrate was concentrated using a rotary evaporator. The obtained crude product was separated by silica gel column chromatography, and the obtained solid was recrystallized to produce a target product, Compound 14, as a solid powder with a yield of 45% (APCI+: C₅₄H₃₁N₃O, measured value 737).

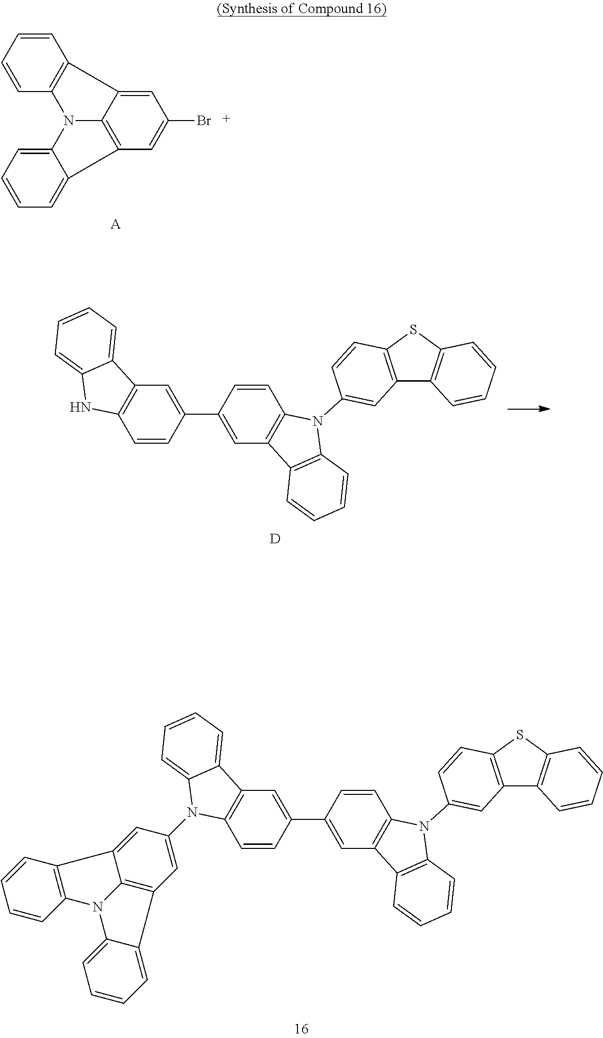

First Synthesis

An indolocarbazole compound A (4 mmol), a carbazole compound D (4 mmol), a palladium catalyst (0.4 mol), a phosphine ligand (1.6 mol), a basic reagent (16 mmol), and toluene (200 mL) were added in a reaction vessel, followed by substituting air in the vessel with nitrogen and stirring while refluxing for 15 hours. After cooling by standing, water was added in the reactant, and extraction of an organic layer was performed. The obtained organic layer was dried with magnesium sulfate anhydrous and filtered, and the obtained filtrate was concentrated using a rotary evaporator. The obtained crude product was re-precipitated to produce a target product, Compound 16, as a solid powder with a yield of 27% (APCI+: C₅₄H₃₁N₃S, measured value 753).

Second Synthesis

An indolocarbazole compound A (7 mmol), a carbazole compound D (7 mmol), a palladium catalyst (0.7 mol), a phosphine ligand (2.8 mol), a basic reagent (28 mmol), and toluene (400 mL) were added in a reaction vessel, followed by substituting air in the vessel with nitrogen and stirring while refluxing for 24 hours. After cooling by standing, water was added in the reactant, and extraction of an organic layer was performed. The obtained organic layer was dried with magnesium sulfate anhydrous and filtered, and the obtained filtrate was concentrated using a rotary evaporator. The obtained crude product was separated by silica gel column chromatography, and the obtained solid was recrystallized to produce a target product, Compound 16, as a solid powder with a yield of 45% (APCI+: C₅₄H₃₁N₃S, measured value 753).

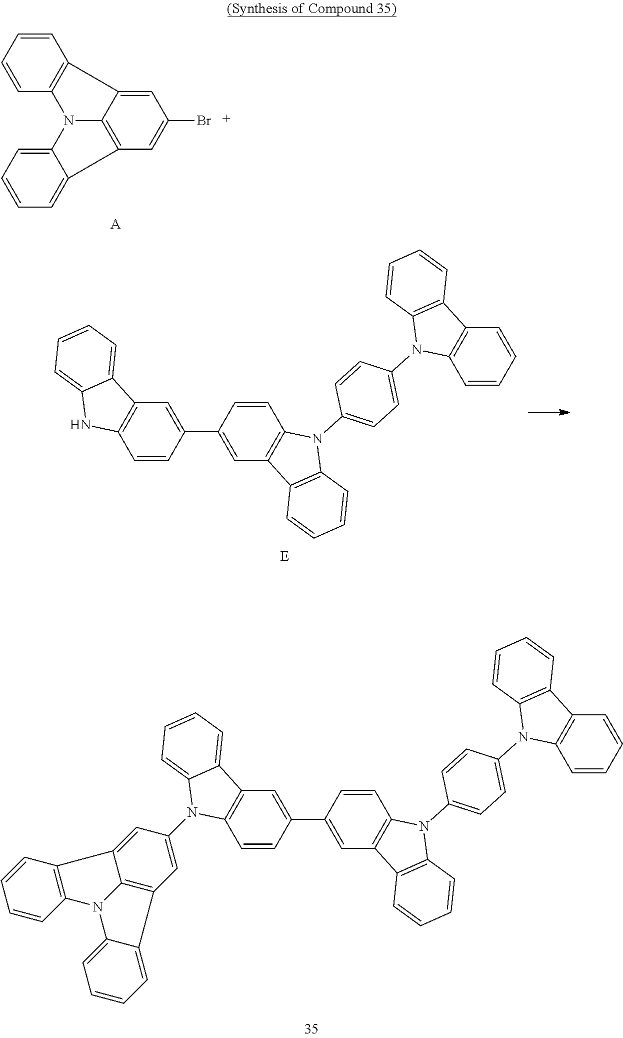

First Synthesis

An indolocarbazole compound A (5 mmol), a carbazole compound E (5 mmol), a palladium catalyst (0.5 mol), a phosphine ligand (2 mol), a basic reagent (20 mmol), and toluene (250 mL) were added in a reaction vessel, followed by substituting air in the vessel with nitrogen and stirring while refluxing for 15 hours. After cooling by standing, water was added in the reactant, and extraction of an organic layer was performed. The obtained organic layer was dried with magnesium sulfate anhydrous and filtered, and the obtained filtrate was concentrated using a rotary evaporator. The obtained crude product was re-precipitated to produce a target product, Compound 35, as a solid powder with a yield of 21% (APCI+: C₆₀H₃₆N₄, measured value 812).

Second Synthesis

An indolocarbazole compound A (7 mmol), a carbazole compound E (7 mmol), a palladium catalyst (0.7 mol), a phosphine ligand (0.7 mol), an basic reagent (2.8 mmol), and toluene (400 mL) were added in a reaction vessel, followed by substituting air in the vessel with nitrogen and stirring while refluxing for 20 hours. After cooling by standing, water was added in the reactant, and extraction of an organic layer was performed. The obtained organic layer was dried with magnesium sulfate anhydrous and filtered, and the obtained filtrate was concentrated using a rotary evaporator. The obtained crude product was separated by silica gel column chromatography, and the obtained solid was recrystallized to produce a target product, Compound 35, as a solid powder with a yield of 50% (APCI+: C₆₀H₃₆N₄, measured value 812).

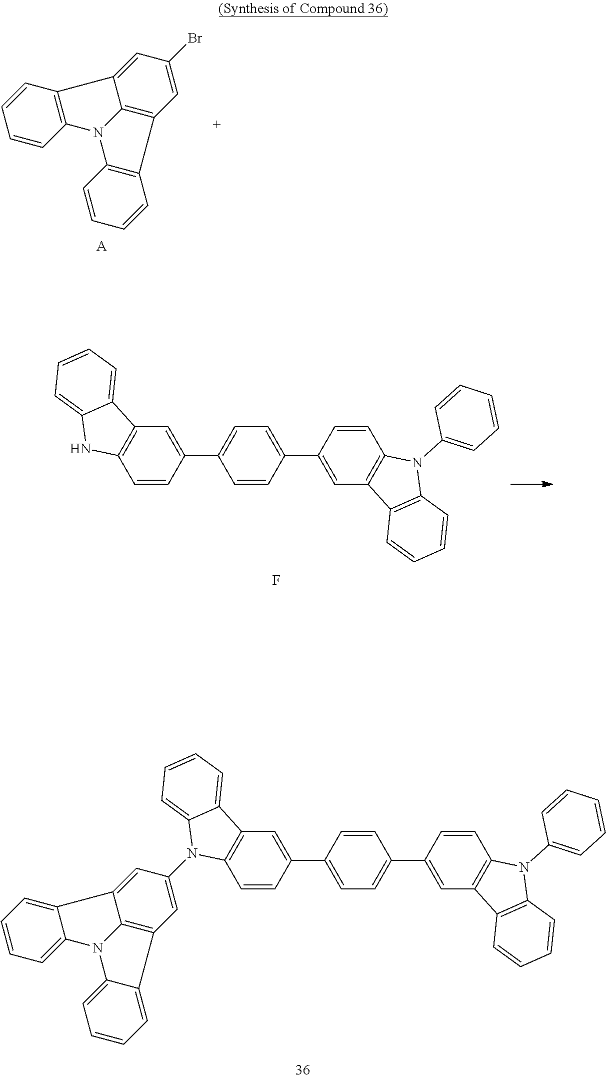

First Synthesis

An indolocarbazole compound A (6 mmol), a carbazole compound F (6 mmol), a palladium catalyst (0.6 mol), a phosphine ligand (2.4 mol), a basic reagent (24 mmol), and toluene (300 mL) were added in a reaction vessel, followed by substituting the air in the vessel with nitrogen and stirring while refluxing for 17 hours. After cooling by standing, water was added in the reactant, and extraction of an organic layer was performed. The obtained organic layer was dried with magnesium sulfate anhydrous and filtered, and the obtained filtrate was concentrated using a rotary evaporator. The obtained crude product was re-precipitated to produce a target product, Compound 36, as a solid powder with a yield of 26% (APCI+: C₅₄H₃₃N₃, measured value 723).

Second Synthesis

An indolocarbazole compound A (4 mmol), a carbazole compound F (4 mmol), a palladium catalyst (0.4 mol), a phosphine ligand (1.6 mol), a basic reagent (16 mmol), and toluene (250 mL) were added in a reaction vessel, followed by substituting air in the vessel with nitrogen and stirring while refluxing for 18 hours. After cooling by standing, water was added in the reactant, and extraction of an organic layer was performed. The obtained organic layer was dried with magnesium sulfate anhydrous and filtered, and the obtained filtrate was concentrated using a rotary evaporator. The obtained crude product was separated by silica gel column chromatography, and the obtained solid was recrystallized to produce a target product, Compound 36, as a solid powder with a yield of 40% (APCI+: C₅₄H₃₃N₃, measured value 723).

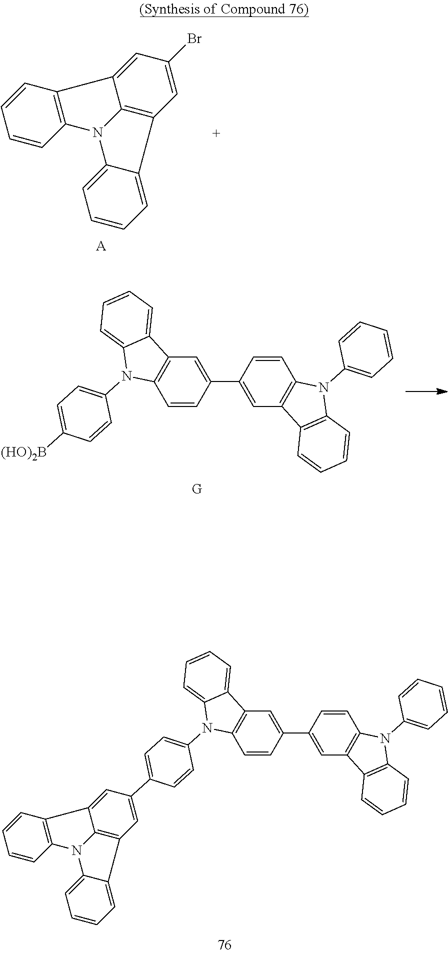

First Synthesis

An indolocarbazole compound A (3 mmol), a carbazole compound G (3 mmol), a palladium catalyst (0.3 mol), a phosphine ligand (1.2 mol), an basic reagent (12 mmol), toluene (200 mL), water (20 mL), and ethanol (10 mL) were added in a reaction vessel, followed by substituting the air in the vessel with nitrogen and stirring while refluxing for 20 hours. After cooling by standing, water was added in the reactant, and extraction of an organic layer was performed. The obtained organic layer was dried with magnesium sulfate anhydrous and filtered, and the obtained filtrate was concentrated using a rotary evaporator. The obtained crude product was separated by silica gel column chromatography, and the obtained solid was recrystallized to produce a target product, Compound 76, as powder state solid with yield of 21% (APCI+: C₅₄H₃₃N₃, measured value 723).

Second Synthesis

An indolocarbazole compound A (5 mmol), a carbazole compound G (5 mmol), a palladium catalyst (0.5 mol), a phosphine ligand (2 mol), a basic reagent (20 mmol), toluene (250 mL), water (25 mL), and ethanol (18 mL) were added in a reaction vessel, followed by substituting the air in the vessel with nitrogen and stirring while refluxing for 21 hours. After cooling by standing, water was added in the reactant, and extraction of an organic layer was performed. The obtained organic layer was dried with magnesium sulfate anhydrous and filtered, and the obtained filtrate was concentrated using a rotary evaporator. The obtained crude product was separated by silica gel column chromatography, and the obtained solid was recrystallized to produce a target product, Compound 76, as a solid powder with a yield of 34% (APCI+: C₅₄H₃₃N₃, measured value 723).

According to the above-described methods, Compounds 1, 14, 16, 35, 36, and 76 were prepared as the materials for an organic EL device. In addition, the following Comparative Compounds 1 and 2 were prepared for comparison.

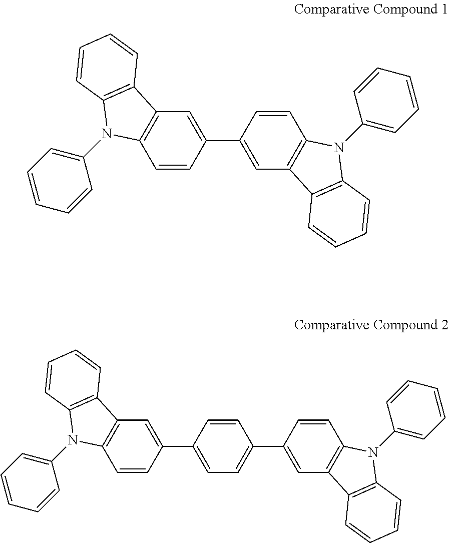 [SMILES: c1ccc(-n2c3ccccc3c3cc(-c4ccc5c(c4)c4ccccc4n5-c4ccccc4)ccc32)cc1 ; c1ccc(-n2c3ccccc3c3cc(-c4ccc(-c5ccc6c(c5)c5ccccc5n6-c5ccccc5)cc4)ccc32)cc1]

Organic EL devices were manufactured using Compounds 1, 14, 16, 35, 36, and 76, or Comparative Compounds 1 and 2, as hole transport materials of a hole transport layer. The substrate 102 was formed using a transparent glass substrate, the anode 104 was formed using ITO to a thickness of about 150 nm, the hole injection layer 106 was formed using 2-TNATA to a thickness of about 60 nm, the hole transport layer 108 was formed to a thickness of about 30 nm, the emission layer 110 was formed using ADN doped with 3% TBP to a thickness of about 25 nm, the electron transport layer 112 was formed using Alq₃ to a thickness of about 25 nm, the electron injection layer 114 was formed using LiF to a thickness of about 1 nm, and the cathode 116 was formed using Al to a thickness of about 100 nm.

With respect to the organic EL devices thus manufactured, the driving voltage, the current efficiency, and the half-life were evaluated. The evaluation results are illustrated in Tables 1 and 2, below. Table 1 includes the results obtained by using the materials synthesized by the first syntheses, and Table 2 includes the results obtained by using the materials synthesized by the second syntheses.

In this case, the current efficiency means the values at 10 mA/cm², and the half-life means luminance half-life necessary for decreasing the luminance to half with an initial luminance of 1,000 cd/m².

TABLE 1

| | | Voltage | Current efficiency | Half-life |
|---|---|---|---|---|
| | HTL | (V) | (cd/A) | (hr) |
| Example 1 | Compound 1 | 6.2 | 7.9 | 2,600 |
| Example 2 | Compound 14 | 6.3 | 8.1 | 2,700 |
| Example 3 | Compound 16 | 6.4 | 7.7 | 2,800 |
| Example 4 | Compound 35 | 6.0 | 7.8 | 2,900 |
| Example 5 | Compound 36 | 6.4 | 7.5 | 3,100 |
| Example 6 | Compound 76 | 6.0 | 8.0 | 2,900 |
| Comparative | Comparative | 8.0 | 5.0 | 1,300 |
| Example 1 | Compound 1 | | | |
| Comparative | Comparative | 7.8 | 5.9 | 1,200 |
| Example 2 | Compound 2 | | | |

TABLE 2

| | | Voltage | Current efficiency | Half-life |
|---|---|---|---|---|
| | HTL | (V) | (cd/A) | (hr) |
| Example 1 | Compound 1 | 6.3 | 7.8 | 2,700 |
| Example 2 | Compound 14 | 6.5 | 8.0 | 2,800 |
| Example 3 | Compound 16 | 6.5 | 7.5 | 2,700 |
| Example 4 | Compound 35 | 6.1 | 7.5 | 3,000 |
| Example 5 | Compound 36 | 6.6 | 7.3 | 3,000 |
| Example 6 | Compound 76 | 6.0 | 7.7 | 2,800 |
| Comparative | Comparative | 8.0 | 5.0 | 1,300 |
| Example 1 | Compound 1 | | | |
| Comparative | Comparative | 7.8 | 5.9 | 1,200 |
| Example 2 | Comnound 2 | | | |

As may be seen in Tables 1 and 2, Compounds 1, 14, 16, 35, 36, and 76 contributed to an organic EL device driven at a lower voltage, when compared to Comparative Compounds 1 and 2. In addition, with respect to the current efficiency, Compounds 1, 14, 16, 35, 36, and 76 realized higher current efficiency, when compared to Comparative Compounds 1 and 2. In addition, the half-life was significantly long for Compounds 1, 14, 16, 35, 36, and 76. It may be seen that the driving at a low voltage, the high efficiency and the long life of an organic EL device may be realized by using Compounds 1, 14, 16, 35, 36, and 76, which include a carbazole coupling compound (with high hole transporting properties) substituted with an indolocarbazolyl group (with high electron tolerance), as the hole transport material.

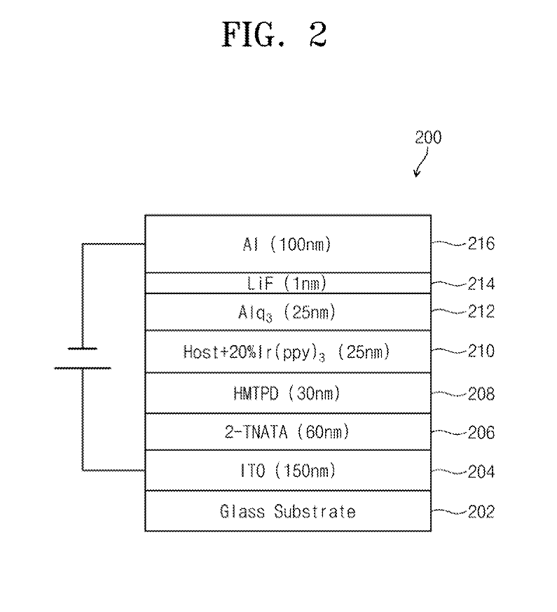

In addition, organic EL devices were manufactured by using Compounds 1, 14, 16, 35, 36, and 76, and Comparative Compounds 1 and 2, as host materials of an emission layer by the above-described manufacturing method. An organic EL device 200 including Compound 1, 14, 16, 35, 36, or 76, or Comparative Compound 1 or 2, as the host material of the emission layer is illustrated in FIG. 2. In the organic EL device 200, a substrate 202 was formed using a transparent glass substrate, an anode 204 was formed using ITO to a thickness of about 150 nm, a hole injection layer 206 was formed using 2-TNATA to a thickness of about 60 nm, a hole transport layer 208 was formed using HMTPD to a thickness of about 30 nm, an emission layer 210 was formed using Compound 1, Compound 14, Compound 16, Compound 35, Compound 36, Compound 76, Comparative Compound 1 or Comparative Compound 2, doped with 20% Ir(ppy)₃ to a thickness of about 25 nm, an electron transport layer 212 was formed using Alq₃ to a thickness of about 25 nm, an electron injection layer 214 was formed using LiF to a thickness of about 1 nm, and a cathode 216 was formed using Al to a thickness of about 100 nm.

With respect to the organic EL devices thus manufactured, the driving voltage, the current efficiency, and the half-life were evaluated. The evaluation results are illustrated in Tables 3 and 4, below. Table 3 includes the results obtained by using the materials synthesized by the first syntheses, and Table 4 includes the results obtained by using the materials synthesized by the second syntheses.

In this case, the current efficiency means the values at 10 mA/cm², and the half-life means luminance half-life necessary for decreasing the luminance to half with an initial luminance of 1,000 cd/m².

TABLE 3

| | | Voltage | Current efficiency | Half-life |
|---|---|---|---|---|
| | HTL | (V) | (cd/A) | (hr) |
| Example 7 | Compound 1 | 4.2 | 30.9 | 1,900 |
| Example 8 | Compound 14 | 4.4 | 30.2 | 2,200 |
| Example 9 | Compound 16 | 4.6 | 29.6 | 2,000 |
| Example 10 | Compound 35 | 4.3 | 29.5 | 2,000 |
| Example 11 | Compound 36 | 4.2 | 30.8 | 2,200 |
| Example 12 | Compound 76 | 4.0 | 30.5 | 2,300 |
| Comparative | Comparative | 5.5 | 28.7 | 1,100 |
| Example 3 | Compound 1 | | | |
| Comparative | Comparative | 5.2 | 25.0 | 1,200 |
| Example 4 | Compound 2 | | | |

TABLE 4

| | | Voltage | Current efficiency | Half-life |
|---|---|---|---|---|
| | HTL | (V) | (cd/A) | (hr) |
| Example 7 | Compound 1 | 4.3 | 30.7 | 2,000 |
| Example 8 | Compound 14 | 4.5 | 30.0 | 2,100 |
| Example 9 | Compound 16 | 4.7 | 29.1 | 1,900 |
| Example 10 | Compound 35 | 4.4 | 29.3 | 2,200 |
| Example 11 | Compound 36 | 4.4 | 30.2 | 2,100 |
| Example 12 | Compound 76 | 4.1 | 30.1 | 2,500 |
| Comparative | Comparative | 5.5 | 28.7 | 1,100 |
| Example 3 | Compound 1 | | | |
| Comparative | Comparative | 5.2 | 25.0 | 1,200 |
| Example 4 | Compound 2 | | | |

As may be seen in Tables 3 and 4, Compounds 1, 14, 16, 35, 36, and 76, could contribute to an organic EL device driven at a lower voltage, when compared to Comparative Compounds 1 and 2. In addition, with respect to the current efficiency, Compounds 1, 14, 16, 35, 36, and 76 could realize higher current efficiency, when compared to Comparative Compounds 1 and 2. In addition, the half-life was significantly long for Compounds 1, 14, 16, 35, 36, and 76. It may be seen that the driving at a low voltage, the high efficiency, and the long life of an organic EL device may be realized by using Compounds 1, 14, 16, 35, 36, and 76, which include a carbazole coupling compound (with high hole transporting properties) substituted with an indolocarbazolyl group (with high electron tolerance), as the host material of the emission layer.

By way of summation and review, the organic EL device in a display apparatus should exhibit high efficiency and long life. The normalization, the stabilization, and the durability of a hole transport layer may be considered to help realize the high efficiency and the long life of the organic EL device.

The embodiments may provide a compound for an organic electroluminescence device having high efficiency and long life.

The embodiments may provide a compound for an organic EL device having high efficiency and long life.

The compound for an organic EL device according to an embodiment may be a carbazole coupled compound (having high hole transporting properties) substituted with an indolocarbazolyl group (having high electron tolerance). Thus, the electron tolerance of the organic EL device may be improved, and the high efficiency and the long life of the organic EL device may be attained. In addition, the driving voltage of the organic EL device may be decreased.

The hole transport material according to an embodiment may include an indolocarbazole group (having high electron tolerance), and the electron tolerance of the organic EL device may be improved, and the high efficiency and the long life of the organic EL device may be realized. In addition, the driving voltage of the organic EL device may be decreased.

The host material according to an embodiment may include an indolocarbazole group (having high electron tolerance), and the electron tolerance of the organic EL device may be improved, and the high efficiency and the long life of the organic EL device may be realized. In addition, the driving voltage of the organic EL device may be decreased.

According to an embodiment, a compound for an organic EL device capable of decreasing a driving voltage and having high efficiency and long life, and an organic EL device using the same may be provided. For example, a compound for an organic EL device having a low driving voltage, high efficiency and long life and manufactured by using the material in an emission layer or in a layer of stacking layers between the emission layer and an anode, and an organic EL device using the same may be provided.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A compound for an organic electroluminescence (EL) device, the compound being represented by the following Formula (1): 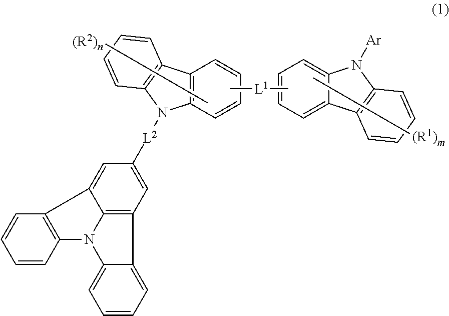
wherein, in Formula (1),
Ar is a substituted or unsubstituted alkyl group, a substituted or unsubstituted aryl group, or a substituted or unsubstituted heteroaryl group,
L¹ and L² are each independently a single bond, a substituted or unsubstituted arylene group, or a substituted or unsubstituted heteroarylene group,
R¹ and R² are each independently hydrogen, deuterium, a halogen atom, a cyano group, a substituted or unsubstituted alkyl group, a substituted or unsubstituted alkoxy group, a substituted or unsubstituted aryl group, a substituted or unsubstituted heteroaryl group, a substituted or unsubstituted triarylsilyl group, or a substituted or unsubstituted trialkylsilyl group, and
m and n are each independently an integer of 1 to 7.

2. The compound for an organic EL device as claimed in claim 1, wherein Ar is a substituted or unsubstituted aryl group having 6 to 24 ring carbon atoms.

3. The compound for an organic EL device as claimed in claim 1, wherein Ar is a substituted or unsubstituted carbazolyl group, a substituted or unsubstituted dibenzofuryl group, or a substituted or unsubstituted dibenzothienyl group.

4. The compound for an organic EL device as claimed in claim 1, wherein L¹ and L² are each independently a single bond or a substituted or unsubstituted arylene group having 6 to 18 ring carbon atoms.

5. The compound for an organic EL device as claimed in claim 1, wherein R¹ and R² are each independently hydrogen or a substituted or unsubstituted aryl group.

6. A hole transport material comprising the compound for an organic EL device as claimed in claim 1.

7. An organic electroluminescence (EL) device, comprising:
an anode;
an emission layer; and
at least one layer between the anode and the emission layer, the at least one layer including the hole transport material as claimed in claim 6.

8. A host material comprising the compound for an organic EL device as claimed in claim 1.

9. An organic electroluminescence (EL) device comprising an emission layer, the emission layer including the host material as claimed in claim 8.
